(19) United States
(12) Patent Application Publication
(10) Pub. No.: US 2012/0190216 A1
(43) Pub. Date: Jul. 26, 2012

(54) ANNEALING TECHNIQUES FOR HIGH PERFORMANCE COMPLEMENTARY METAL OXIDE SEMICONDUCTOR (CMOS) DEVICE FABRICATION

(75) Inventors: Kevin K. Chan, Staten Island, NY (US); Eric C. Harley, Lagrangeville, NY (US); Isaac Lauer, Mahopac, NY (US); Kam-Leung Lee, Putnam Valley, NY (US); Paul A. Ronsheim, Hopewell Junction, NY (US)

(73) Assignee: International Business Machines Corporation, Armonk, NY (US)

(21) Appl. No.: 13/097,931

(22) Filed: Apr. 29, 2011

Related U.S. Application Data
(60) Provisional application No. 61/434,618, filed on Jan. 20, 2011.

(51) Int. Cl. H01L 21/268; B82Y 40/00

(52) U.S. Cl. 438/799; 977/755

(57) ABSTRACT

A semiconductor structure is provided. In some cases, an absorber having a low deposition temperature is applied to at least a portion of the structure. At least a portion of the structure is subjected to a long flash anneal process.

### CROSS-REFERENCE TO RELATED APPLICATIONS

This patent application claims the benefit of U.S. Provisional Patent Application Ser. No. 61/434,618 filed on Jan. 20, 2011, and entitled “ANNEALING TECHNIQUES FOR HIGH PERFORMANCE COMPLEMENTARY METAL OXIDE SEMICONDUCTOR(CMOS) DEVICE FABRICATION.” The disclosure of the aforementioned Provisional Patent Application Ser. No. 61/434,618 is expressly incorporated herein by reference in its entirety for all purposes.

### FIELD OF THE INVENTION

The present invention relates to the electrical and electronic arts, and, more particularly, to semiconductor fabrication and the like.

### BACKGROUND OF THE INVENTION

Complementary metal oxide semiconductor (CMOS) technology is employed in a number of applications, such as, for example, microprocessors, microcontrollers, static random access memory (SRAM), and the like, and even for some analog applications. Continued progress has been made in reducing the node size in CMOS semiconductor device fabrication technologies. The 22 nm node is expected to be the next step following 32 nm technology.

### SUMMARY OF THE INVENTION

Principles of the invention provide annealing techniques for high performance complementary metal oxide semiconductor (CMOS) device fabrication. In one aspect, an exemplary method includes the steps of providing a semiconductor structure; and subjecting at least a portion of the structure to a long flash anneal process.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

Techniques of the present invention can provide substantial beneficial technical effects. For example, one or more embodiments provide enhanced chip performance and/or quality.

These and other features and advantages of the present invention will become apparent from the following detailed description of illustrative embodiments thereof, which is to be read in connection with the accompanying drawings.

### BRIEF DESCRIPTION OF THE DRAWINGS

FIGS. 1 and 2 show an exemplary comparison between standard and long ms-flash time temperature profiles, according to an aspect of the invention;

FIGS. 3 and 4 show another exemplary comparison between standard and long ms-flash time temperature profiles, according to an aspect of the invention;

FIG. 5 shows an exemplary re-growth rate of pre-amorphised silicon according to an aspect of the invention;

FIGS. 6 and 7 show an exemplary comparison of arsenic extension junction generation between an RTA+laser and a long flash anneal, according to an aspect of the invention;

FIGS. 8 and 9 show an exemplary comparison of boron extension junction generation between an RTA+laser and a long flash anneal, according to an aspect of the invention;

FIG. 10 depicts measured flash light reflectivity with and without absorber, according to an aspect of the invention;

FIG. 11 presents a comparison of As junction formation with standard and long-ms flash, according to an aspect of the invention;

FIG. 12 presents a comparison of As junction formation with different Ge PAI and long-ms Flash, according to an aspect of the invention;

FIG. 13 presents a comparison of B junction formation with standard and long ms-flash anneal, according to an aspect of the invention;

FIG. 14 presents a comparison of B junction formation with different Ge PAI and long ms-flash anneal, according to an aspect of the invention;

FIG. 15 presents a comparison of B junctions with different energy, doses and flash Tᵢ temperatures, according to an aspect of the invention:

FIG. 16 depicts As junction motion with different number of long ms-flash anneals, according to an aspect of the invention;

FIG. 17 presents a plot of As junction depth with different number of long-ms flash anneals, according to an aspect of the invention;

FIG. 18 presents data for a Boron junction with 1 and 3 multiple long ms-flash anneals, according to an aspect of the invention;

FIG. 19 plots I_{d} vs. V_{gs} of PFETs and NFETs at V_{ds} of 50 mV and 1V, according to an aspect of the invention;

FIG. 20 presents a comparison of Vtₛₐₜ vs. LPoly for NFETs with long ms-flash and RTA+laser, according to an aspect of the invention;

FIG. 21 presents a comparison of Vtₛₐₜ vs. LPoly for PFETs with long ms-flash and RTA+laser, according to an aspect of the invention;

FIG. 22 presents a comparison of DIBL vs. LPoly for NFETs with long ms-flash and RTA+laser, according to an aspect of the invention;

FIG. 23 presents a comparison of DIBL vs. LPoly for PFETs with long ms-flash and RTA+laser, according to an aspect of the invention;

FIG. 24 presents a comparison of I_{d} vs. V_{gs} for NFETs with and without corner leakages for flash and RTA+laser, according to an aspect of the invention;

FIG. 25 presents a cross-sectional schematic illustration of corner leakage:

FIG. 26 presents a schematic process flow, according to an aspect of the invention;

FIG. 27 presents overlay plots of a comparison of the XRD results for the 1.5% SiC epi with 3 different S/D I/I and No S/D implant (control) after long 2.5 ms high temperature 1300° C. flash anneal, according to an aspect of the invention;

FIGS. 28-38 are FIGS. 1-11 reproduced from U.S. patent application Ser. No. 12/760,620, IBM Attorney Docket Number YOR920090608US1, filed Apr. 15, 2010, entitled LOW-TEMPERATURE ABSORBER FILM AND METHOD OF FABRICATION, of inventors Katherina E. Babich et al.; in particular:

FIG. 28 is a graph illustrating the preamorphized silicon re-growth rate as a function of temperature;

FIG. 29 includes FTIR spectra of prior art amorphous carbon only films deposited at 550° C. 480° C. and 400° C.;

FIG. 30 is a pictorial representation (through a cross sectional view) depicting an amorphous carbonitride film having an extinction coefficient of greater than 0.15, an emissivity of greater than 0.8 and a low hydrocarbon content on a surface of a substrate;

FIG. 31 is a pictorial representation (through a cross sectional view) depicting a structure including a substrate having amorphous carbonitride films deposited on adhesion promoting layers;

FIG. 32 includes a plot of R_{S} measurements performed on amorphous carbon only layers (ACL; prior art) and amorphous carbonitride (ACN; invention) films;

FIG. 33 includes FTIR spectra of Samples 1, 2, 3 and 4 from Table 5 herein;

FIG. 34 is an SEM micrograph showing an intact amorphous carbonitride film after flash anneal at 1300° C.;

FIG. 35 is a plot of wavelength (nm) vs. reflectivity (%) for various samples including an SOI substrate with no absorber coating, an SOI substrate with a prior art amorphous carbon only absorber coating, and amorphous carbonitride absorber coating;

FIG. 36 is a plot of energy set point (kJ) vs. front surface temperature jump (° C.) for SOI substrates with an absorber coating and without an absorber coating;

FIG. 37 is a plot of flash annealing (intermediate temperature Tᵢ-peak temperature Tₚ) vs. % implanted carbon in Si in the source/drain regions of an NFET within Example 7 herein; and

FIG. 38 is a plot of flash annealing (intermediate temperature Tᵢ-peak temperature Tₚ) vs. SiC S/D sheet resistivity (ohm/square) for various samples within Example 7 herein.

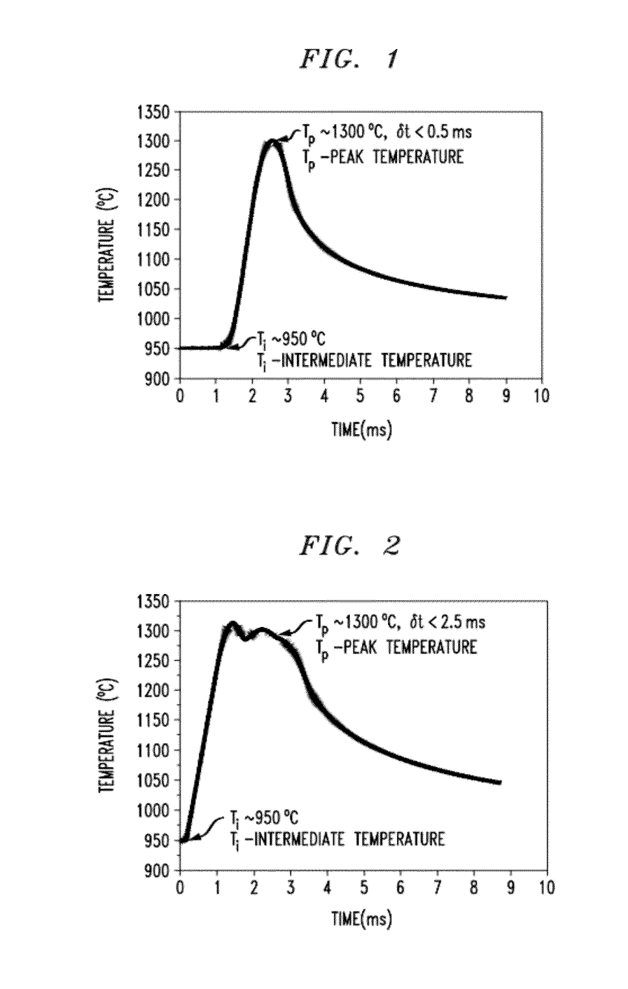

### DETAILED DESCRIPTION OF PREFERRED EMBODIMENTS

For 22 nm technology and beyond, where gate pitch is 80 nm or less, there is a difficult trade-off to increase the source-drain (SD) area for lower contact resistance while taking into account the need for adequate final spacer width to prevent the encroachment of SD to extension, which worsens device short channel effect (SCE) performance. This trade-off tends to drive the use of a thinner extension offset spacers, and the corresponding reduction of spike rapid thermal annealing (RTA) temperature for device centering. Although subsequent diffusionless laser and/or flash anneal can improve the dopant activation, defects anneal and activation typically deteriorates with lower starting spike RTA temperature. Diffusionless ms-laser- and/or flash-only approaches offer inadequate defect anneal and profile control to fully optimize device performance. One or more embodiments provide a high temperature long ms-anneal approach to meet the conflicting needs described above for scaled device centering and/or shallow junction optimization.

One or more embodiments provide sub-20 nm abrupt USJ formation with long ms-flash with sub-2 nm dopant motion control.

One or more embodiments provide a new combination of long millisecond (1-2.5 ms) flash anneal at high peak temperature (1200-1300° C.) and a new absorber with low deposition temperature (<400° C.) which generate highly activated (Rs˜500 ohm/sq), sub-20 nm abrupt (<3 nm/decade) N+ and P+ junctions. Details on exemplary embodiments of the new absorber are provided in U.S. patent application Ser. No. 12/760,620, IBM Attorney Docket Number YOR920090608US1, filed Apr. 15, 2010, entitled LOW-TEMPERATURE ABSORBER FILM AND METHOD OF FABRICATION, of inventors Katherina E. Babich et al., which is reproduced herein in pertinent part and also expressly incorporated herein by reference in its entirety for all purposes. This new approach also provides sub-2 nm T\N⁺ and P⁺ junction dopant motion control with multiple long ms-flash which are required for precision device centering and doping for 22 nm and beyond devices. High performance SOI (silicon-on-insulator) CMOS has been achieved with single long ms-flash and matches well with CMOS created with spike RTA+laser. In addition, long ms-flash NFETs (n-type field effect transistors) were found to need only ˜½ of the B halo dose and exhibit no anomalous corner leakage which is sometime found in spike RTA+laser NFETs. These results demonstrate better B halo localization in NFETs with long ms-flash, in one or more embodiments.

Thus, one or more embodiments provide high performance CMOS integrated with e-SiGe (PFETs), e-SIC(NFETs) source/drain, poly-pre-doped and long millisecond (1-5 ms) anneal at high peak temperature (1200-1350° C.) for extension/SD junctions formation and SiC source/drains strain optimization. Advantageously, one or more embodiments provide integration schemes which resolve the major conflicts in high performance CMOS device fabrication with e-SiGe (PFETs) and e-SiC for NFETs where substantial SiC strain loss results with the current high temperature RTA 1065° C./spike anneal for extension/SD activation and junction diffusion for device Coy optimization.

One aspect of one or more embodiments involves the replacement of the incompatible RTA 1065° C./spike implant junction anneal which causes the significant strain loss in SiC source/drain with the high temperature (1200-1350° C.) long ms (1-5 ms) flash anneal. The appropriate high temperature long millisecond (1-5 ms)-flash anneal will, in one or more embodiments, enable the rapid re-growth (<1 ms) of implanted SiC source/drain region without loss of substitutional carbon in SiC source/drain which is the primary source for the loss of SiC strain during standard RTA 1065° C./spike anneal, and/or at the same time provide better dopant activation and appropriate diffusion for reducing device external Rs reduction and optimal device Coy. In this manner, higher performance CMOS device performance results from the more well activated abrupt junctions and improved channel mobility for both PFETs (p-type field effect transistors) and NFETs with strain e-SiGe and e-SiC source/drains.

Ultra Shallow Junction (USJ) Formation with High Temperature Long MS-Flash

New Low temperature absorber coating: In connection with a series of experiments, USJ formation with long ms-anneal was carried out using a Mattson tool, known per se to the skilled artisan and available from Mattson Technology, Inc. 47131 Bayside Pkwy., Fremont, Calif. 94538 USA and/or Mattson Technology Canada, Inc., 605 West Kent Avenue, Vancouver, British Columbia V6P 6T7. Given the teachings herein, the skilled artisan will be able to implement one or more embodiments of the invention using the aforesaid Mattson tool.

The standard and long ms-flash time-temperature profiles are shown in FIGS. 1 & 2, respectively. The time at peak temperature (Tₚ) of 1300° C. for standard flash is <0.5 ms whereas 1-2.5 ms time duration at Tₚ can be achieved with long ms-flash. With available intensity, the temperature jump for long ms-flash from intermediate (Tᵢ) to Tₚ is limited to ˜350° C. Thus for a Tₚ of 1300° C. a high Tᵢ of 950° C. will have to be used in at least some instances, and this may create undesirable dopant motion or process.

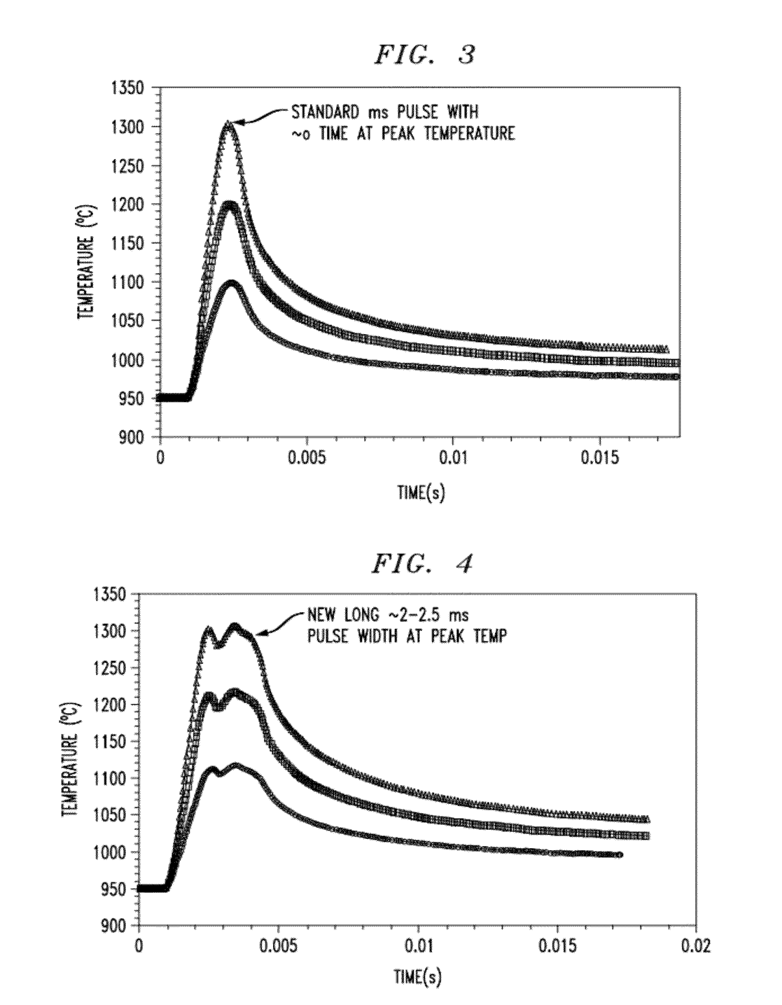

FIGS. 3 & 4 show another comparison of the standard millisecond flash anneal (<<1 ms at peak temperature of 1300° C.) with the new long (>1 ms at peak temperature of 1300° C.) millisecond flash anneal.

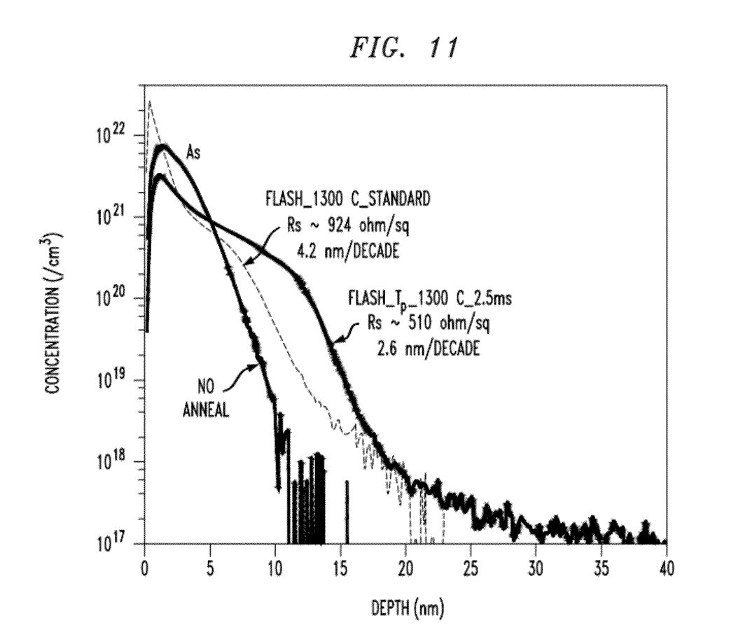

One or more embodiments advantageously employ a new absorber for long ms-flash. The absorber deposition temperature is <400° C. so that premature PAI SPE re-growth is avoided. With the new absorber, as seen in FIG. 10, reflectivity of flash drops from 70 to 10% at peak intensity (λ˜300 nm) and this enables a larger temperature range (Tₚ-Tᵢ˜550° C.) for USJ and other process optimization.

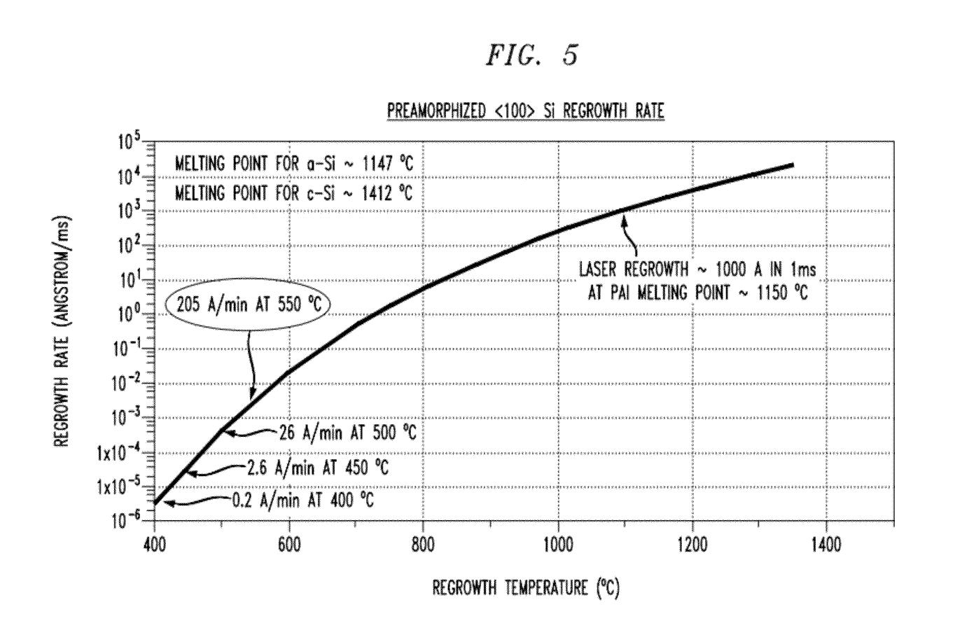

FIG. 5 shows that the re-growth rate of the pre-amorphised Si is >1000 Angstroms in ˜one millisecond. This mean that during long-millisecond flash anneal, the implanted amorphous Si junctions get quickly re-grown at high temperatures. This results in better junction dopant activation and junction defects anneal. For SiC implanted source/drain in SOI since the source/drain SOL recrystallization happens in ˜1 ms or less, it will significantly reduce the out-diffusion of substitutional carbon in SiC and the strain of the SiC is preserved.

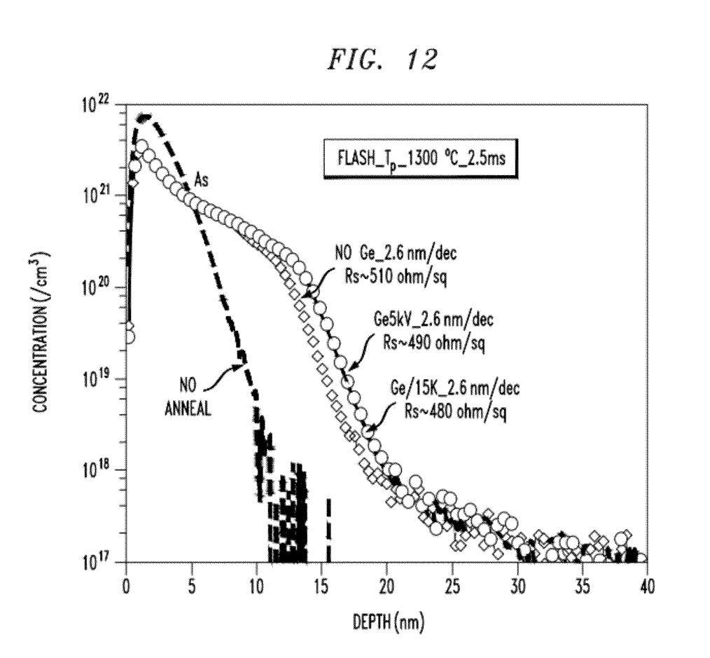

Sub-20 nm abrupt N+ and P+ USJ formation: FIG. 11 shows a comparison of As junctions with standard and long ms-flash. A more box-like, abrupt and lower Rs (sheet resistance) As junction is achieved with long ms-flash, i.e., 2.6 vs. 4.2 nm/decade and Rs˜510 vs. 924 ohm/sq. In time scale of standard ms-flash, predominant As motion is at concentration<5E18/cm³ where transient enhanced diffusion (TED) dominates. With long ms-flash, concentration enhanced diffusion is observed relative to As junction with standard flash. The enhanced As diffusion ˜3 nm at 1E20/cm³ is close to the estimated As diffusion in crystalline Si. This suggests improved damaged re-growth with long ms-flash. FIG. 12 shows a comparison of As junctions with various Ge pre-amorphous implant (PAI) (5 & 15 kV), no Ge and with same As ion implantation (I/I). As shown, similar box-like junction with ˜same Rs are formed with long 2.5 ms flash. These results suggest possible rapid dissolution of Ge PAI end-of-range (EOR) damages and re-growth during long ms-flash and final As junction profile is dominated by As diffusion in crystalline Si.

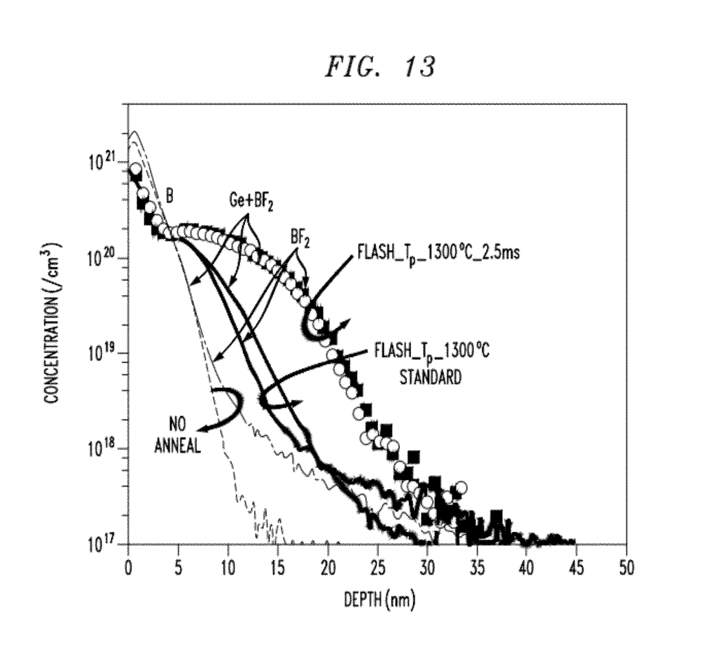

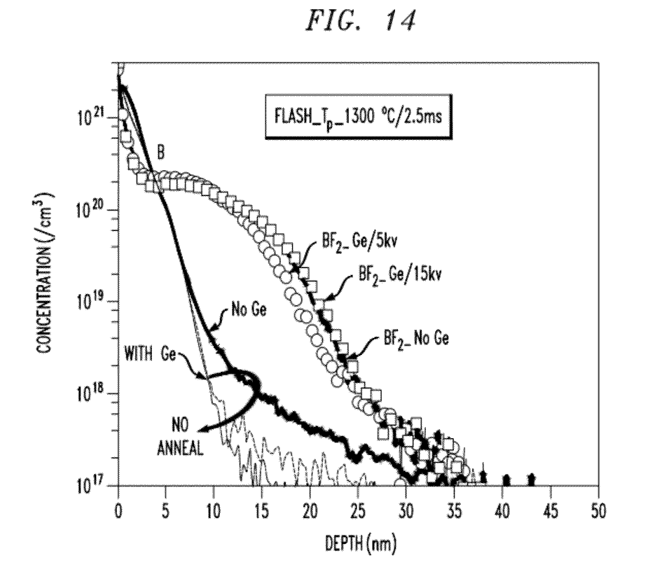

FIG. 13 shows a comparison of B junctions with standard and long ms-flash for cases with and without Ge PAI. As shown, a more box-like B junction is achieved with long 2.5 ms-flash. In time-scale of standard flash, B diffusion happens mostly above 1E18/cm³ and is enhanced with Ge PAI whose EOR provides excess interstitials for enhanced B diffusion at this stage. However, the final B junctions is similar with long 2.5 ms-flash with and without Ge PAI suggesting rapid dissolution of Ge PAI EOR damages and re-growth like those for As+ Ge PAI. This is demonstrated in FIG. 14 where similar B junctions are achieved with different Ge PAI (5 and 15 kV) and BF₂ I/I only. FIG. 15 demonstrates an approach of using higher BF₂ ion implant energy, close and use of flash anneal absorber coating to enable lower Tᵢ with same Tₚ long ms-flash to create box-like B junction with higher concentration (>2E20/cm²), shallower Xj (19 vs. 21 nm), lower Rs (496 vs. 630 ohm/sq) and similar junction abruptness of ˜3 nm/decade.

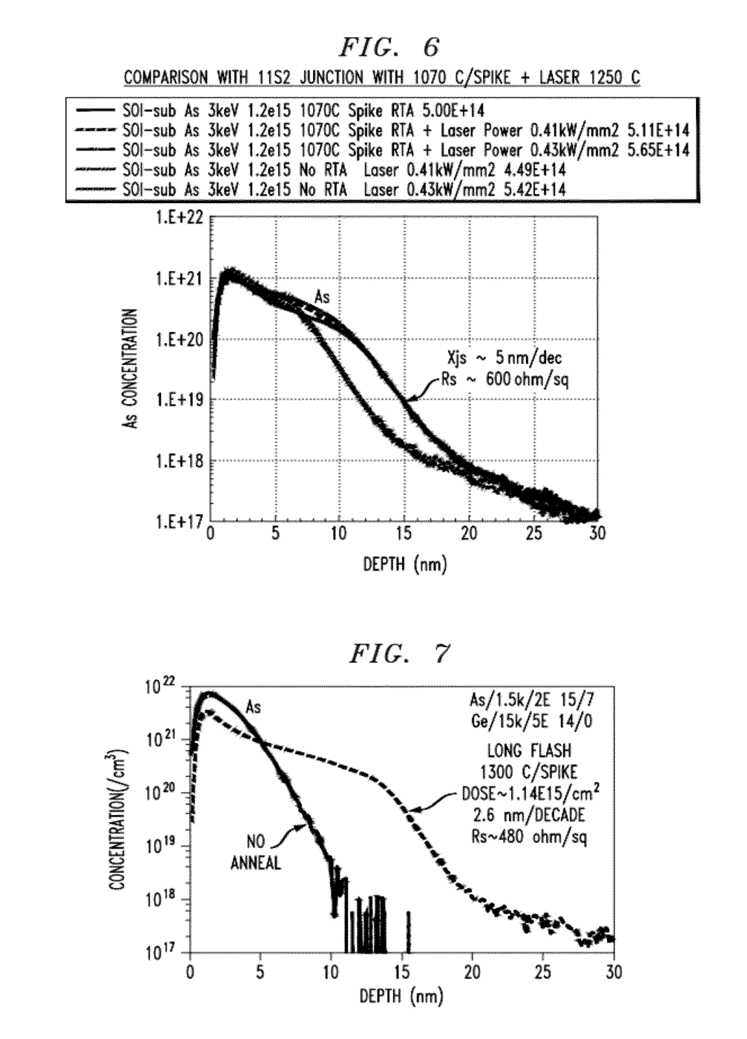

FIGS. 6 and 7 present a comparison with 11S2 junction with 1070° C. spike+laser 1250° C. In particular, FIGS. 6 and 7 show the comparison of arsenic extension junction generated by RTA+laser and the long (2.5 ms) flash anneal. For similar junction depth, better activated and more abrupt arsenic extension junction is generated with single long millisecond flash anneal.

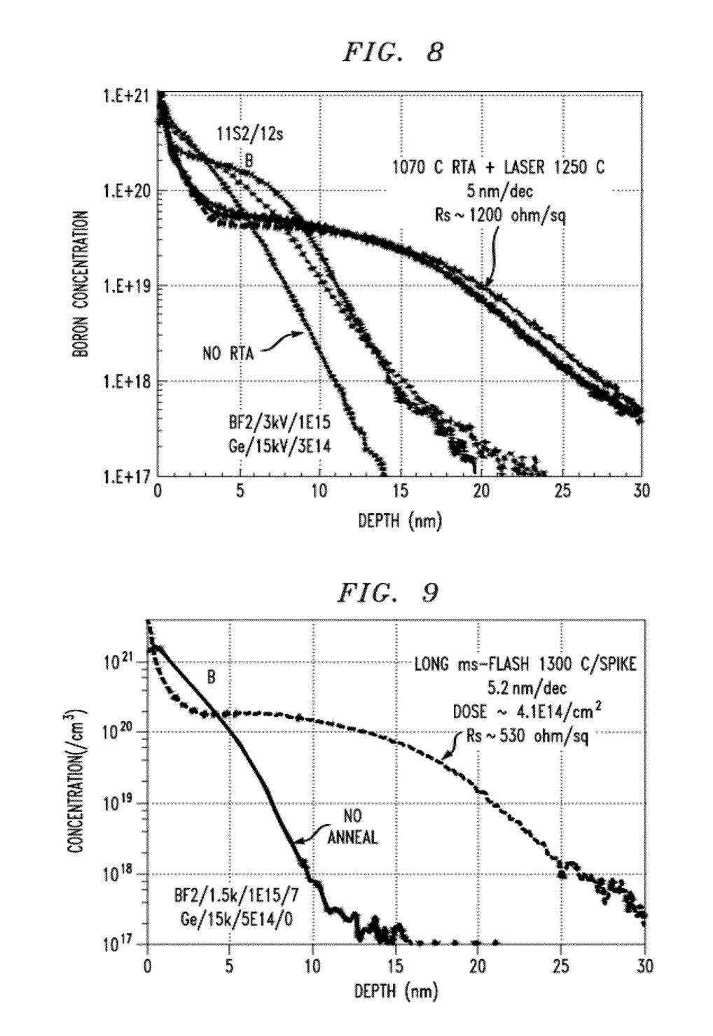

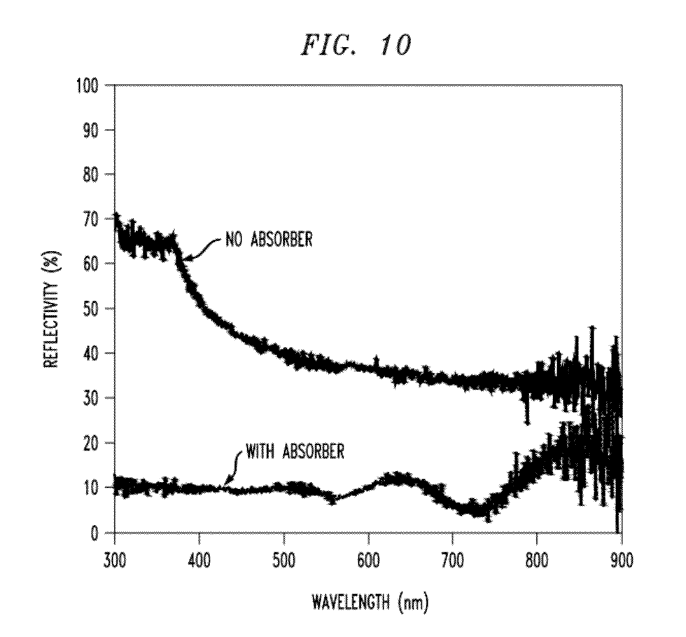

FIGS. 8 and 9 present a comparison of boron extension junction generated with RTA+laser and the long (2.5 ms) flash anneal. As shown, similar boron junction depth and abruptness, better activated boron junctions (530 vs. 1200 ohm; sq) is achieved with single long millisecond flash anneal.

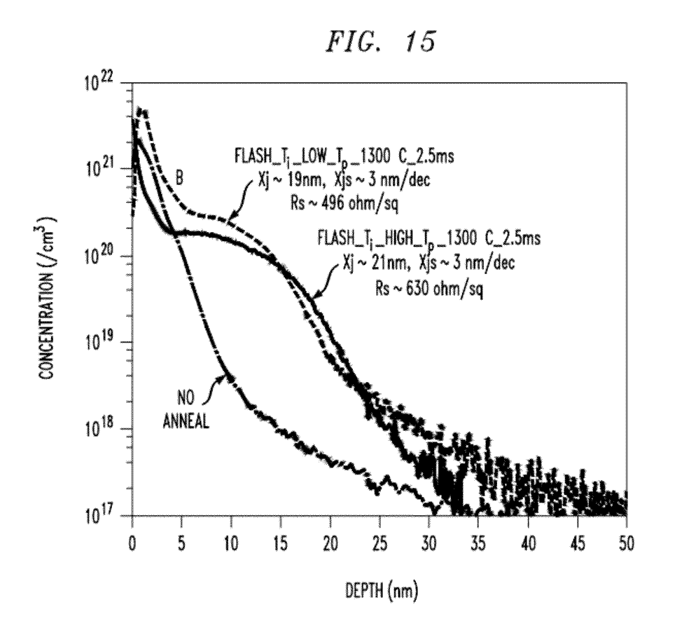

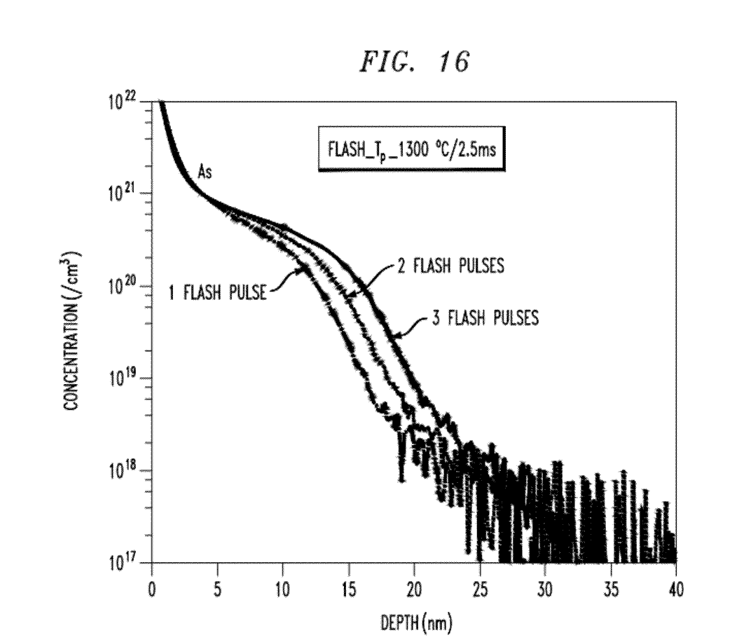

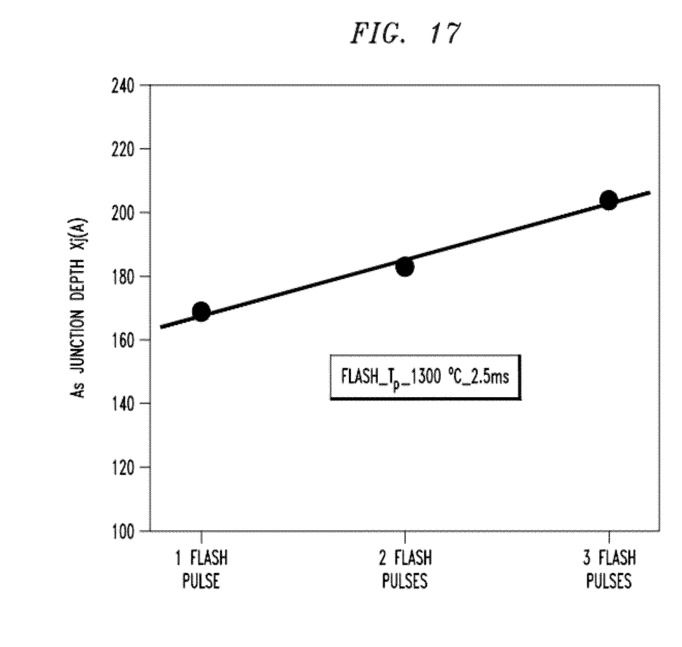

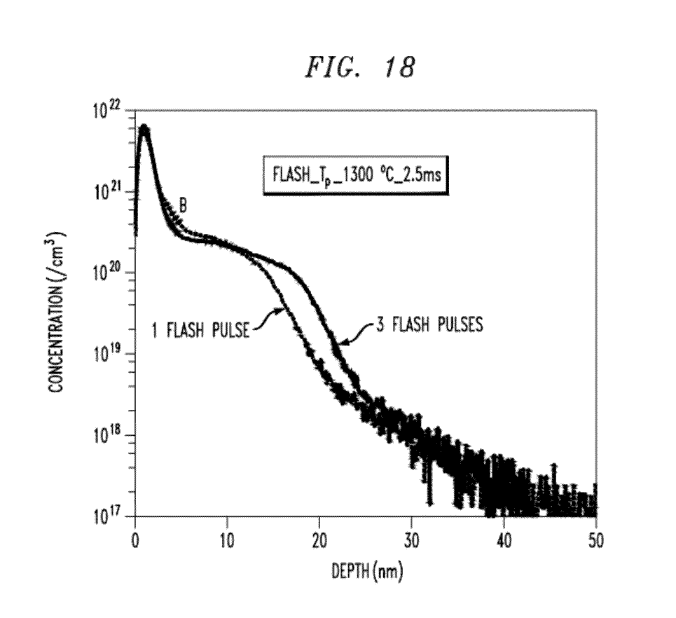

Sub-2 nm N+ and P+ dopant motion control: FIG. 16 shows the As junction profiles after 1, 2 and 3 long ms-flash pulses. As shown, the As junction depth increases uniformly with additional number of long ms-flashes after first long ms-flash while junction abruptness remain˜same. FIG. 17 shows a plot of As junction depth vs. number of long ms-flash anneal pulses. As shown, a linear increase of junction depth Xj˜1.6 nm per additional long ms-flash is achieved after the first ms-flash pulse. FIG. 18 demonstrates ˜3 nm B diffusion motion control is achieved between 1 and 3 long ms-flashes with similar B junction abruptness. This feature of sub-2 nm dopant motion control for N⁺ and P⁺ junctions with multiple long ms-flash is particularly useful for precision device centering and doping in sub-10 nm thick Si body devices, i.e., FinFETs (fin-type multi-gate FETs), and ETSOI (extremely thin SOD.

Devices with Long-MS-Flash and Spike RTA+ Laser

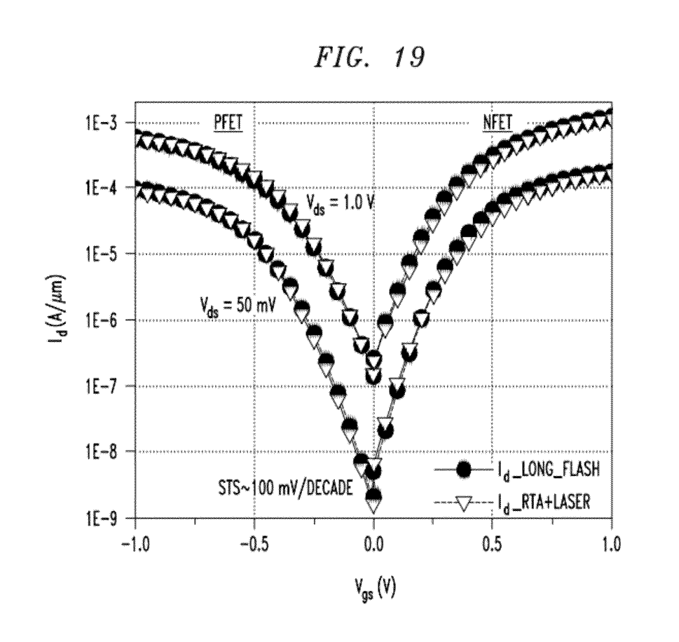

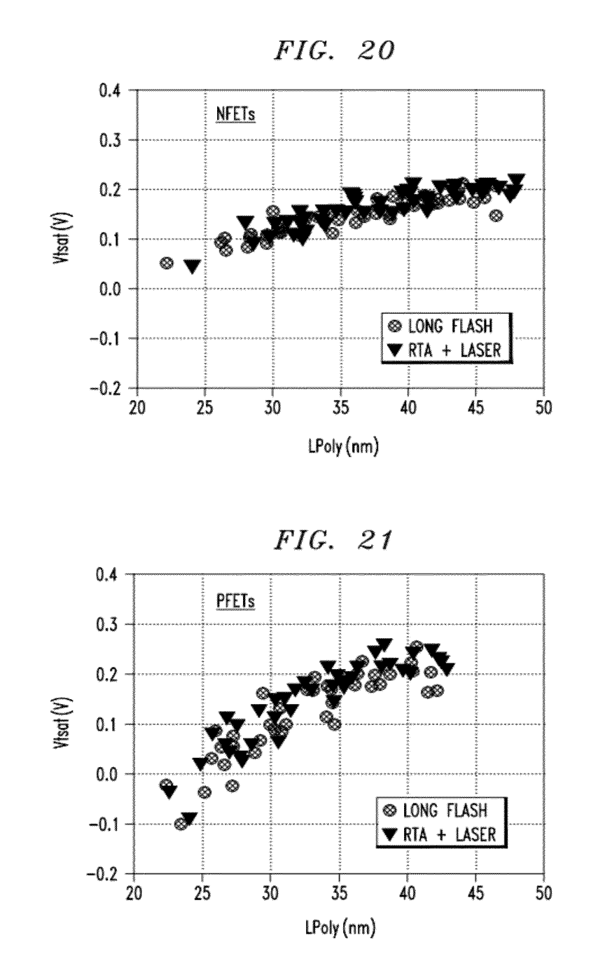

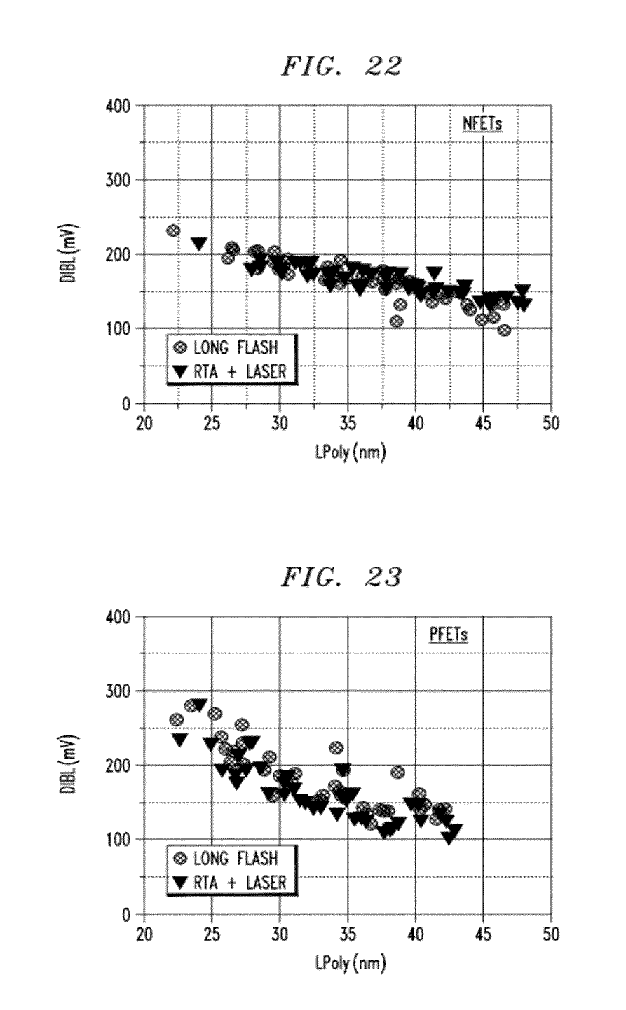

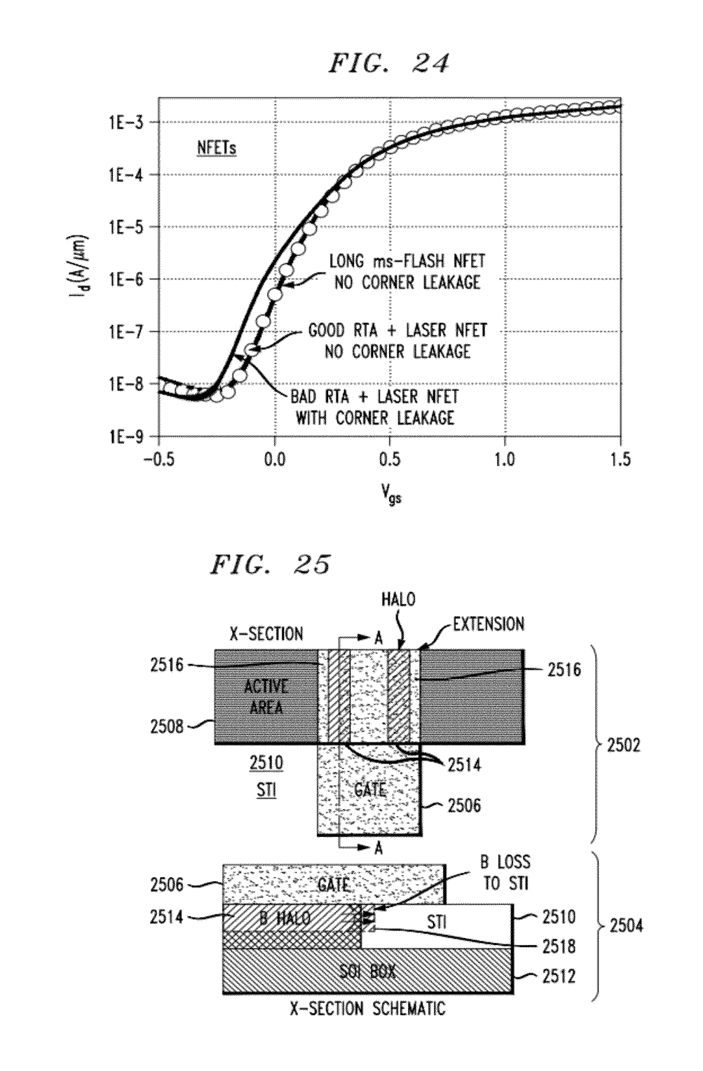

For experimental purposes, long ms-flash has been implemented in a SOI route with a Poly/SiON stack to compare with spike RTA+laser for an initial assessment of device centering and performance. SMT, e-SiGe and dual stress liner are used for achieving high performance n- and p-type FETs. Pre-doping and activation were done for poly gates before S/D to achieve ˜same Tinv which was otherwise compromised by the reduced diffusion from long ms-flash. For a MG/HK (metal-gate/high-k) process, gate pre-doping should not be needed in one or more embodiments. With the same extension I/I, device centering with single long-ms flash to match spike RTA+laser device performance can be achieved with a thinner offset spacer. For centered PFETs, similar As halo dose was needed. However, for centered NFETs, only ˜½ of B halo dose was needed in long-ms flash NFETs. This suggests better localization of B halo with long-ms flash compared with spike RTA+laser. FIG. 19 shows a comparison of I_{d} vs. V_{gs} of PFETs & NFETs achieved with long ms-flash and spike RTA+laser. As shown, high performance PFETs & NFETs with matching I_{d} vs. V_{gs} have been obtained for long ms-flash and spike RTA+laser. Sub-threshold slope of ˜100 mV/dec has been achieved for both NFETs & PFETs. FIGS. 20-23 show a comparison of Vtₛₐₜ and DIBL vs. Lpoly for NFETs & PFETs. These results show similar DIBL (˜200 mV) and Vtₛₐₜ roll-off which suggest similar SCE for both NFETs & PFETs generated with long ms-flash and spike RTA+laser. FIG. 24 shows I_{d} vs. V_{gs} for NFETs with long ms-flash and spike RTA+laser. For typical spike RTA+laser NFETs, the I_{d} vs. V_{gs} matches that with long ms-flash. For given experimental process, there was a statistical population of spike RTA+laser devices which exhibited B halo loss to the STI edge (FIG. 25) which then results in a lower-Vt current leakage path at the corner of the device. No corner leakage was found in long ms-flash NFET which further indicates better B halo localization with long ms-flash and opens up possibility of a simplified STI module with no extra steps used to inhibit B out-diffusion.

With continued reference to FIG. 25, portion 2502 is a top view while portion 2504 is across-section view taken along line A-A in portion 2502. Note the gate 2506, active area 2508, shallow trench isolation (STI) 2510, and SOI box 2512. Note also B halo portions 2514 and extensions 2516. The loss of B to the STI portion is seen at 2518.

### Exemplary Process Flow

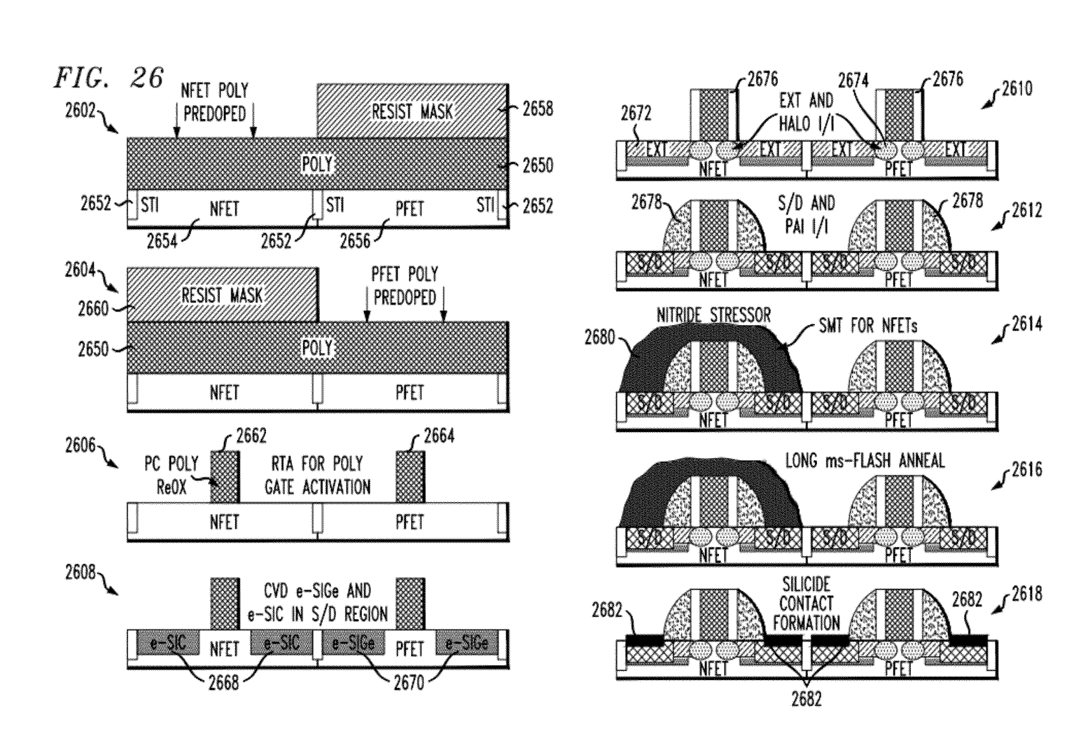

FIG. 26 presents a schematic process flow for NFETs and PFETs with e-SiGe and e-SiC S/D and long-millisecond flash anneal for extension halo and S/D activation. Note a substrate with a poly layer 2650 on top and with STI portions 2652, as well as a portion of the substrate 2654 wherein an NFET will be fabricated and a portion of the substrate 2656 wherein a PFET will be fabricated. As seen at 2602, provide a first resist mask 2658 and pre-dope the portion of the poly wherein the NFET will be fabricated. As seen at 2604, provide a second resist mask 2660 and pre-dope the portion of the poly wherein the PFET will be fabricated. In 2606, after a suitable process to form the gates 2662, 2664 of the NFET and PFET respectively, carry out RTA for activation of the POLY gates, obtaining re-oxidized PC POLY as indicated.

In 2608, carry out chemical vapor deposition (CVD) of e-SiC in the source-drain regions 2668 of the NFET and chemical vapor deposition (CVD) of e-SiGe in the source-drain regions 2670 of the PFET. In 2610, carry out ion implantation for the extensions 2672 and halo regions 2674. Note shallow junction spacers 2676, also known as extension junction spacers. In 2612, carry out ion implantation for the source-drain regions 2668, 2670 and PAI (not separately numbered). Note deep source-drain spacers 2678, also known as wide spacers. In 2614, employ the stress memorization technique (SMT) for the NFETs using nitride stressor 2680. In 2616, carry out the long ms-flash anneal process as described elsewhere herein, optionally first applying the appropriate absorber material (in some cases, no absorber is used, as described elsewhere). In a non-limiting example, the absorber material (omitted from the drawings for clarity) is applied just prior to the annealing step 2616, as a blanket over the entire surface, with a thickness of at least about 3000 Angstroms. The absorber blanket is then removed after the annealing is complete. The absorber material may include graphite and may have a high thermal conductivity in at least some instances. In 2618, carry out silicide contact formation to obtain contacts 2682.

### Exemplary X-Ray Diffraction (XRD) Results

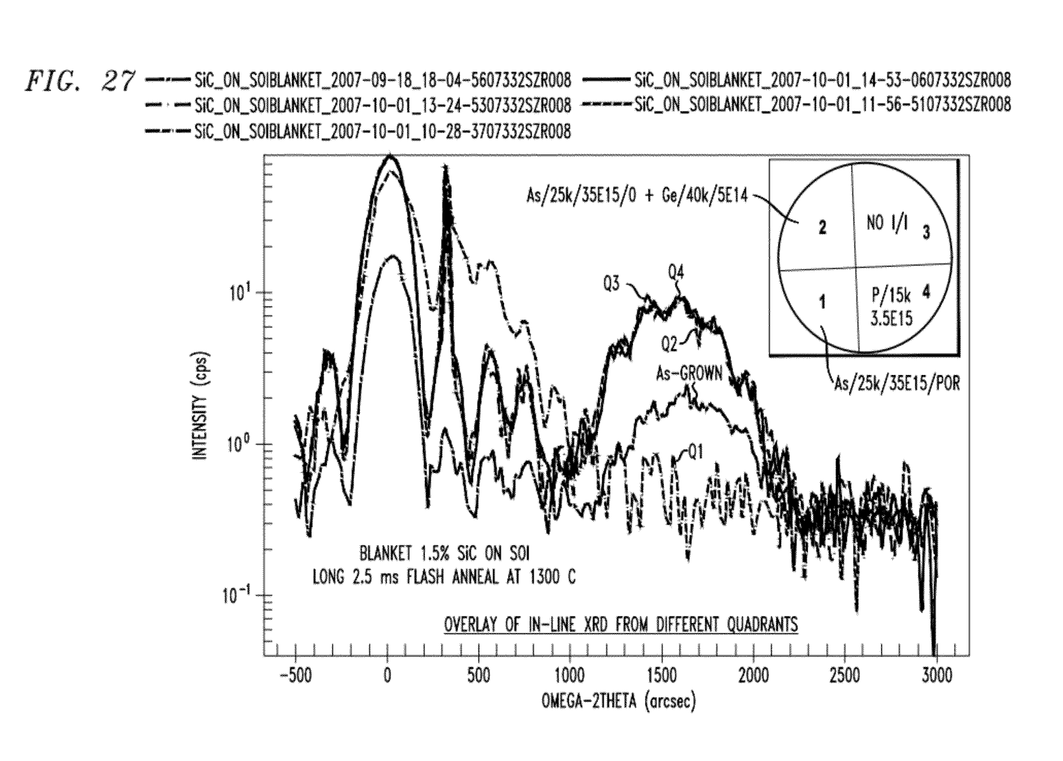

FIG. 27 shows overlay plots of an experimental comparison of the XRD results for the 1.5% SiC epi with three different S/D I/I and no S/D implant (control) after long 2.5 ms high temperature 1300° C. flash anneal. The good XRD intensity and similar XRD peak at the same OMEGA-2THETA position indicates that for the S/D I/I with conditions shown in quadrants two and four, the strain in the SiC is fully restored after long 2.5 ins high temperature 1300° C. flash anneal with these S/D I/I conditions.

### Conclusion and Recapitulation

High temperature (1200-1300° C.) long ms-flash anneal (1-2.5 ms), optionally combined with a new absorber, has been developed to generate better activated and more box-like abrupt sub-20 nm N⁺ & P⁺ junctions over standard ms-flash anneal (in some cases, no absorber is used, as described elsewhere). Sub-2 nm N⁺ & P⁺ dopant motion control had been demonstrated with multiple long-ms flash. High performance SOI CMOS has been achieved with single long ms-flash and matched well with CMOS created with spike RTA+laser. Long ms-flashed NFETs show no corner leakage which is sometimes found in spike RTA+laser NFETs. These results demonstrate the application of high temperature long ms-anneal for improved junction activation, precision device centering and/or doping control for 22 nm & beyond device technology, in accordance with one or more embodiments of the invention.

Given the discussion thus far, it will be appreciated that, in general terms, an exemplary method, according to an aspect of the invention, includes the step of providing a semiconductor structure (see, e.g., steps 2612, 2614, and 2616 of FIG. 26; many different types of semiconductor structures can benefit from annealing techniques disclosed herein and a number of non-limiting examples have been set forth—other materials such as metal portions, insulators, and the like may also be present in the semiconductor structure). An optional further step, used in some instances (e.g. with high-reflectivity structures and/or to save power) includes applying an absorber to at least a portion of the structure. The absorber has a low deposition temperature. A still further step includes subjecting at least a portion of the structure to a long flash anneal process.

In a non-limiting example of a semiconductor structure, the structure includes a plurality of NFET portions 2654 and a plurality of PFET portions 2656. The structure also includes a plurality of shallow trench isolation regions 2652 separating the NFET portions and the PFET portions. In addition, the structure includes a plurality of NFET source-drain regions 2668 associated with the NFET portions, which have been subjected to e-SiC chemical vapor deposition (see, e.g. step 2608). Even further, the structure includes a plurality of PFET source-drain regions 2670 associated with the PFET portions, that have been subjected to e-SiGe chemical vapor deposition (again, see, e.g., step 2608). Still further, the structure includes a plurality of NFET gates 2662 intermediate given ones of the source-drain regions associated with the NFET portions, and a plurality of PFET gates 2664 intermediate given ones of the source-drain regions associated with the PFET portions. The structure even further includes a plurality of NFET halo regions intermediate the given ones of the source-drain regions associated with the NFET portions and the NFET gates, and a plurality of PFET halo regions intermediate the given ones of the source-drain regions associated with the PFET portions and the PFET gates. Please refer to step 2610 and note that only a single one of the halo regions (in this case, a PFET halo region) has been given reference character 2674 to avoid clutter.

In some instances, the long flash anneal process includes a peak temperature of about 1300 degrees centigrade maintained for about 2.5 milliseconds. In some cases where the absorber is used, the low deposition temperature is no greater than about 400 degrees centigrade.

The different ranges of parameters set forth herein can be combined in any desired combination.

In some instances, the structure provided in the providing step has a gate pitch of no more than about 80 nanometers.

In some cases, the method further comprising maintaining the semiconductor structure at an intermediate temperature, Tᵢ, of about 300 to about 900 degrees centigrade prior to the long flash anneal process. In some applications, the intermediate temperature is about 400 to about 900 degrees centigrade.

In some instances, the intermediate temperature is about 300 to about 400 degrees centigrade and the semiconductor structure comprises a silicide. In such cases, the long flash anneal process could include, for example, a peak temperature of about 900 to about 950 degrees centigrade maintained for about 1 to about 5 milliseconds.

In one or more embodiments, the long flash anneal process includes a peak temperature of about 1200 to about 1300 degrees centigrade maintained for about 1 to about 2.5 milliseconds; and in some embodiments, the long flash anneal process includes a peak temperature of about 1200 to about 1350 degrees centigrade maintained for about 1 to about 5 milliseconds.

In some cases, the long flash anneal process includes a peak temperature of about 950 to about 1300 degrees centigrade maintained for about 1 to about 2.5 milliseconds; in some embodiments, the long flash anneal process includes a peak temperature of about 950 to about 1250 degrees centigrade maintained for about 1 to about 2.5 milliseconds; and in some embodiments, the long flash anneal process comprises a peak temperature of about 1150 to about 1300 degrees centigrade maintained for about 1 to about 5 milliseconds.

In some instances, the structure provided in the providing step comprises a silicon body having a thickness of no more than about 10 nanometers.

In one or more embodiments, the low deposition temperature is no greater than about 450 degrees centigrade; in some embodiments, the low deposition temperature ranges from about 250 degrees centigrade to about 450 degrees centigrade; and in some embodiments, the low deposition temperature ranges from about 350 degrees centigrade to about 400 degrees centigrade.

In some instances, the long flash anneal process includes a peak temperature of about 1300 degrees centigrade maintained for about 2.5 milliseconds, and the low deposition temperature is no greater than about 400 degrees centigrade; and in some instances, the long flash anneal process includes a peak temperature of about 1200 to about 1350 degrees centigrade maintained for about 1 to about 5 milliseconds, and the low deposition temperature ranges from about 250 degrees centigrade to about 450 degrees centigrade.

In one or more embodiments, in the applying step, the absorber includes an amorphous carbonitride film. In some cases, the amorphous carbonitride film has an extinction coefficient of greater than 0.2 and an emissivity of greater than 0.8. In some cases, the subjecting step includes causing electromagnetic radiation having at least one wavelength between 190 nm and 1000 nm to be absorbed by the absorber.

In some instances, the long flash anneal process includes a peak temperature of about 1200 to about 1350 degrees centigrade maintained for about 1 to about 5 milliseconds; the low deposition temperature ranges from about 250 degrees centigrade to about 450 degrees centigrade; and, in the applying step, the absorber comprises an amorphous carbonitride film. In some cases, the amorphous carbonitride film has an extinction coefficient of greater than 0.2 and an emissivity of greater than 0.8. In some cases, the subjecting step includes causing electromagnetic radiation having at least one wavelength between 190 nm and 1000 nm to be absorbed by the absorber.

In some cases, the peak temperature is no more than about 1100 degrees centigrade. In some cases, peak temperature ranges specified elsewhere as about 1200 to about 1350 degrees centigrade can instead range from about 1100 to about 1350 degrees centigrade; peak temperatures at or near 1100 degrees centigrade are believed to be particularly useful for gate stacks.

Thus, one or more techniques disclosed herein can be used to anneal a variety of structures, such as, for example, junctions, gate stacks such as metal gate stacks, silicides, and the like. It is believed that one or more embodiments are especially helpful for use with metal gate stacks, which tend to be sensitive. Furthermore, use of an absorber is optional, but may be helpful to reduce power requirements or for highly reflective substrates such as Silicon on Insulator (SOI). In such cases, the dynamic range (temperature rise from intermediate to peak temperature) may be limited without use of the absorber. In some cases, the absorber will increase the dynamic range to about 500 to about 600 degrees centigrade.

In some instances, the structure is a metal high-k gate stack.

In a typical case, the structure will be at ambient temperature and will be heated to an intermediate temperature, Tᵢ. In some cases, there will be little or no dwell time at Ti (say, 1 millisecond) before the lamp of the Mattson tool is activated. However, in other cases, a more significant dwell time at Tᵢ may be appropriate (say, a few seconds) before activating the lamp. In some cases, regardless of whether an absorber is employed, the dwell time at Ti may range from about zero to about five seconds.

It should be noted that all ranges for intermediate temperature, peak temperature, dwell time, time at peak, and related parameters are, in general, equally applicable for cases with and without absorber use.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

Reproduction of Pertinent Portions of U.S. patent application Ser. No. 12/760,620

For purposes of this portion of the present application, it will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

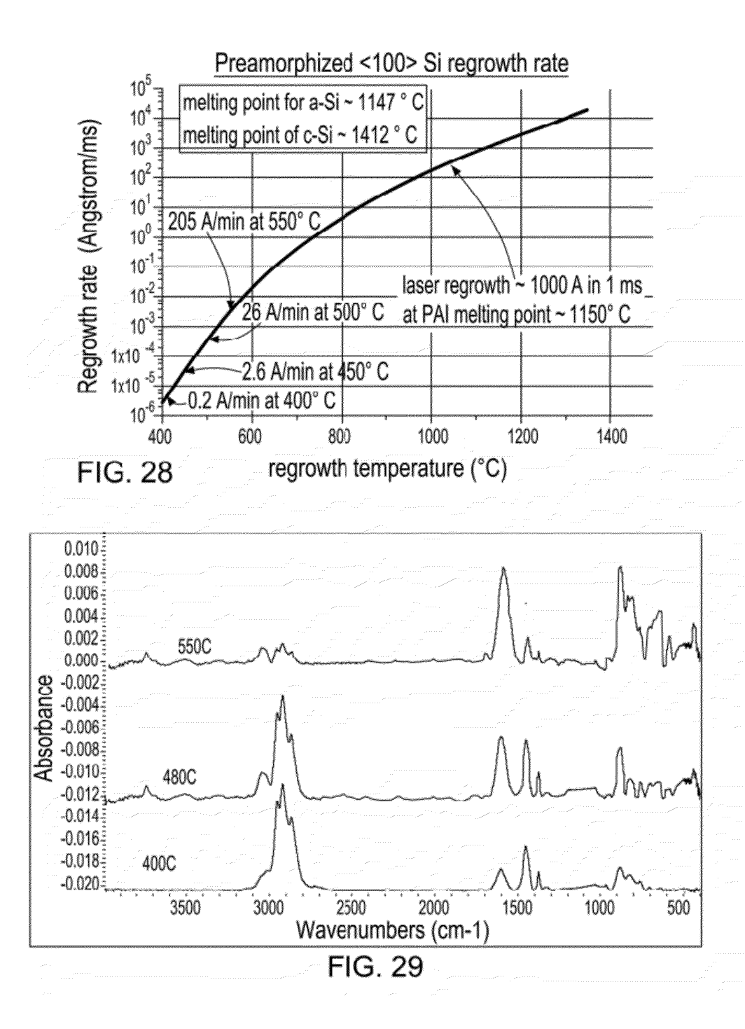

It has been determined through experimentation that in order to achieve a sufficient amorphous carbon only absorbent film, as defined by a k greater than 0.15, an emissivity of about 0.8 or greater, and a film with a minimum of hydrocarbon in it as observed by FTIR, it was necessary to deposit an amorphous carbon only layer (ACL) at 550° C. This is undesirable as the constantly shrinking sizes of transistors put an unavoidable limitation on the processing temperatures of devices. When scaling down the dimensions of metal oxide semiconductor field effect transistor (MOSFET) devices, ultra-shallow contacts and extremely abrupt junctions between the source/drain electrodes and the channel are needed in order to suppress short channel effects. At the same time, the source/drain contacts must be highly doped to keep parasitic resistances as small as possible. Current MOSFET fabrication schemes employ ion implantation for the amorphization and subsequent dopant introduction into a silicon crystal lattice. Silicon amorphization reduces dopant atom channeling during implantation, thereby allowing ultra-shallow junction formation. Although ion implantation offers a number of advantages, the inherent damage to the crystal lattice structure contributes to the mobility degradation in the final device structures. Lattice repair via the application of an annealing step is thus appropriate. It has been determined that preamorphized silicon (PAI) regrowth during deposition of the amorphous carbon layer at 550° C. (Sample 1. Table 1) hinders dopant activation at higher subsequent anneals. During the ACL deposition process, the PAI growth rate for implanted wafers is significant. FIG. 28 shows PAI re-growth rate as a function of temperature. At deposition temperatures of greater than 400° C., PAI regrowth was observed and at 550° C. deposition temperature PAI re-growth rate was approximately 205 Å/min. This hinders dopant activation if PAI is regrown at a much higher temperature (greater than 1000° C.) during laser or flash anneals. Therefore, some of the device schemes can not use absorbing layers deposited at temperatures of greater than 400° C., as it promotes implant diffusion, increases junction surface resistance/interface reaction, and re-growth of high k oxide interfaces.

One potential solution is to lower the deposition temperature of amorphous carbon only films, however as the deposition temperature of the amorphous carbon only films was decreased below 550° C., hydrocarbon content in the film increased rapidly which reduced the absorptive capabilities of the film, k was reduced and emissivity was reduced. As detailed in Table 1, the normalized hydrocarbon content rapidly increases as the deposition temperature is reduced from 550° C. to 480° C. and 400° C. As summarized in Table 1, the k decreased with lower deposition temperature.

TABLE 1
Deposition Conditions and extinction coefficient
(k) values for amorphous carbon only films

| | Temper- | Pres- | | | | | CH peak |
|---|---|---|---|---|---|---|---|
| Sam- | ature | sure | HFRF | C₃H₆ | He | | area/thick- |
| ple | (° C.) | (torr) | (watts) | (sccm) | (sccm) | k | ness (μm) |
| 1 | 550 | 6 | 785 | 600 | 325 | 0.51 | 1 |
| 2 | 480 | 6 | 785 | 600 | 325 | 0.14 | 4 |
| 3 | 400 | 6 | 785 | 600 | 325 | 0.03 | 6 |

FTIR analysis of the resultant amorphous carbon only films (See, FIG. 29) revealed that the absorptions at 2900-2700 cm⁻¹, which were attributed to sp³ C—H, and the absorption at 1440 cm⁻¹ and 1370 cm⁻¹, which were attributed to sp³ CH₃ bending, increased dramatically relative to the sp² C═C stretching vibration at 1600 cm⁻¹ as the deposition temperature was decreased from 550° C. to 480° C. to 400° C. with all other deposition conditions held constant. The lower deposition temperature contributed to incomplete fragmentation of the carbon precursor, which in turn, resulted in higher percentage of CH hydrocarbon bonding in the final amorphous carbon only film. This effect is captured in the normalized hydrocarbon content value.

The increased hydrocarbon content lowered the extinction coefficient (k) of the amorphous carbon only films and resulted in a higher level of outgassing during laser and flash anneals. Higher extinction coefficient (k) is desirable because it results in greater absorbance and minimizes reflectance variations from the underlying substrate.

The overall higher hydrocarbon content adversely affects the optical properties of the film, and lowers the extinction coefficient (k), and the emissivity of the film making the film more transparent to the impinging laser.

In some instances, an improved electromagnetic radiation absorber is provided that comprises, consists essentially of or consists of, an amorphous carbonitride (ACN) film having an extinction coefficient of greater than 0.15, and an emissivity of greater than 0.8. In some cases, the amorphous carbonitride film can be characterized as having a low hydrocarbon content as observed by FTIR. ACN films having the low hydrocarbon content, minimize outgassing during a subsequent laser annealing or flash annealing process. The ACN films can be easily removed after annealing by plasma oxygen ashing. Such an amorphous carbonitride film represents an improvement over conventionally used amorphous carbon only films.

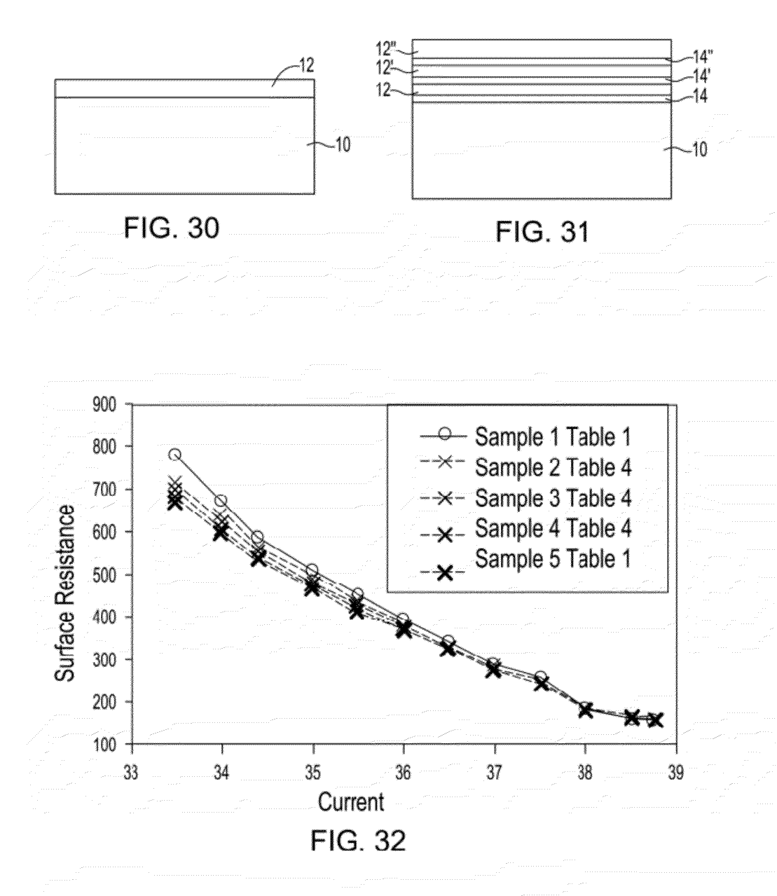

Reference is now made to FIG. 30 which is a pictorial representation of one case in which an amorphous carbonitride film 12 having the aforementioned properties, i.e., extinction coefficient, emissivity and optionally low hydrocarbon content, is formed on a surface of a substrate 10. The substrate 10 can be a semiconductor material, a dielectric material, a conductive material or any multilayered combination thereof. In one embodiment, the substrate 10 is a multilayered combination of at least a semiconductor material, a dielectric material and a conductive material, wherein the semiconductor material is a semiconductor substrate, the dielectric material is a patterned gate dielectric and the conductive material is a patterned gate electrode that is located atop the patterned gate electrode.

When a semiconductor material is employed as an element of substrate 10, the semiconductor material can include, but is not limited to Si, Ge, SiGe, SiC, SiGeC, GaAs, GaN, InAs, InP and all other III/V or II/VI compound semiconductors. The semiconductor material may also comprise an organic semiconductor or a layered semiconductor such, as for, example. Si/SiGe, a silicon-on-insulator (SOI), a SiGe-on-insulator (SGOI) or a germanium-on-insulator (GOI). In some embodiments of the invention, the semiconductor material is a Si-containing semiconductor material that includes silicon. The semiconductor material may be doped, undoped or contain doped and undoped regions therein. The semiconductor material can include a single crystal orientation or it may include at least two coplanar surface regions that have different crystal orientations (the latter semiconductor material can be referred to as a hybrid orientation substrate). The semiconductor material can be process utilized techniques well known to those skilled in the art to include one or more well regions, and/or one or more isolation regions. The semiconductor material can also be processed utilizing techniques well known to those skilled in the art to include one or more semiconductor devices atop an uppermost surface of the semiconductor substrate.

When a dielectric material is employed as an element of substrate 10, the dielectric material can include an organic insulator, an inorganic insulator or any combination thereof including multilayers. In some cases, the dielectric material is an oxide, a nitride, and/or an oxynitride. In yet another case, the dielectric material has a dielectric constant, as measured in a vacuum of equal to, or greater than, the dielectric constant of silicon oxide.

When a conductive material is employed as an element of substrate 10, the conductive material can include, for example, a doped Si-containing material, an elemental metal, an alloy of an elemental metal, a metal silicide, a metal nitride or any combination thereof including multilayers.

It is observed that the semiconductor material, dielectric material and/or conductive material may be part of a device or structure, which may be discrete or interconnected.

As stated above, and as illustrated in FIG. 30, an amorphous carbonitride film 12 is formed atop the substrate 10. The amorphous carbonitride film 12 that is formed has an extinction coefficient of greater than 0.15. Typically, the amorphous carbonitride film 12 has an extinction coefficient from 0.15 to 0.6, more typically the amorphous carbonitride film 12 has an extinction coefficient from 0.15 to 0.4.

The amorphous carbonitride film 12 also has an emissivity of greater than 0.8. Typically, the amorphous carbonitride film 12 has an emissivity from 0.8 to 0.95. More typically, film 12 has an emissivity from 0.85 to 0.92.

A further feature of the amorphous carbonitride film 12 is that it has a minimum hydrocarbon content as measured by FTIR. By “a minimum of hydrocarbon content as observed by FTIR” it is meant a normalized hydrocarbon content less than 3 as defined by integrating under the C—H stretching peak in the FTIR spectra from 3170-2750 cm⁻¹ and dividing the integrated peak area by the film thickness in microns.

The thickness of the amorphous carbonitride film 12 that is formed may vary depending on the conditions in which the amorphous carbonitride film 12 is deposition. Typically, the amorphous carbonitride film 12 that is formed atop the substrate 10 has a thickness from 50 nm to 5000 nm, with a thickness from 100 nm to 500 nm being more typical. Other thicknesses can also be employed so long as the thickness does not interfere with the amorphous carbonitride film being employed as an absorbing layer for exposures to various wavelengths of electromagnetic radiation including, for an example, an exposure wavelength between 190 nm and 1000 nm.

The amorphous carbonitride film 12 can be formed utilizing any low temperature (e.g., of less than, or equal to, 450° C.) deposition process. Suitable examples of low temperature deposition processes that can be used in forming the amorphous carbonitride film 12 include, but are not limited to chemical vapor deposition (CVD) and plasma enhanced chemical vapor deposition (PECVD). In one embodiment of the invention, the amorphous carbonitride film 12 is formed utilizing a low temperature PECVD process. As stated above, any deposition process can be used in forming the amorphous carbonitride film 12 having the above properties so long as the deposition temperature is less than, or equal to, 450° C. In one embodiment of the invention, the amorphous carbonitride film 12 having the above properties can be produced using a deposition temperature from 250° C. to 450° C. In yet another embodiment of the invention, the amorphous carbonitride film 12 having the above properties can be produced using a deposition temperature from 350° C. to 400° C.

In one embodiment of the invention, the amorphous carbonitride film 12 having the above properties can be produced using a combination of at least a carbon precursor source, and a nitrogen source. An oxidant is also typically, but not necessarily always, employed to facilitate decomposition, fragmentation and hydrogen removal. Such a combination of gases can be referred to herein as a reactant gas mixture. The reactant gas mixture may further include an inert gas such as helium or argon. The inert gas may be introduced as a separate component of the reactant gas mixture or it can be present within at least one of the carbon precursor source, the nitrogen source and the oxidant.

In some cases, the amorphous carbonitride film 12 having the above properties can be produced using a single carbonitride precursor that includes both carbon and nitrogen in the molecule. An oxidant is also typically, but not necessarily always, employed in this embodiment of the invention as well.

The carbon precursor source that can be employed in the invention is selected from alkanes, alkenes, alkynes and mixtures thereof. The carbon precursor sources may be linear, branched, and/or cyclic. In one embodiment of the invention, the carbon precursor sources have a minimal C/H ratio. By “minimal C/H ratio” it is meant less than 3 hydrogens for every carbon atom in the precursor.

The term “alkane” denotes a chemical compound that consists only of the elements carbon and hydrogen (i.e. hydrocarbons), wherein these atoms are linked together exclusively by single bonds (i.e., they are saturated compounds). In one embodiment of the invention, the alkane includes from 1 to 22, typically from 1 to 16, more typically, from 1 to 12 carbon atoms.

The term “alkene” denotes an unsaturated chemical compound containing at least one carbon-to-carbon double bond. In one embodiment, the alkene is an acyclic alkene, with only one double bond and no other functional groups. In such an embodiment, the acrylic alkene forms a homologous series of hydrocarbons with the general formula CₙH₂ₙ, wherein n is an integer from 2 to 22, typically 2 to 16, more typically 2 to 12 carbon atoms.

The term “alkyne” denotes a hydrocarbon that has a triple bond between two carbon atoms, with the formula CₙH₂ₙ₋₂, wherein n is an integer from 2 to 22, typically 2 to 16, more typically 2 to 12 carbon atoms. Alkynes are traditionally known as acetylenes.

Some examples of typical carbon precursor sources that can be employed in forming the amorphous carbonitride film 12 include, but are not limited to ethylene, propylene, butene, acetylene, and/or methyl acetylene. In some cases, propylene (C₃H₆) is employed as the carbon precursor source.

The nitrogen source that can be employed in forming the amorphous carbonitride film 12 can be selected from nitriding sources including, but not limited to nitrogen, ammonia, amines, azides, and/or hydrazines. In some cases, nitrogen (N₂) and/or ammonium (NH₃) is employed as the nitrogen source. The oxidant that can be employed in forming the amorphous carbonitride film 12 can be selected from oxidizing sources including oxygen, nitrous oxide, water, and/or ozone. In some cases, oxygen is employed as the oxidant.

Although any combination of carbon precursor source, nitrogen source and oxidant can be employed in forming the amorphous carbonitride film 12, some instances employ propylene (C₃H₆) as the carbon precursor source, nitrogen (N₂) or ammonium (NH₃) as the nitrogen source, and oxygen (O₂) as the oxidant. Such a reactant gas mixture can be used as is or diluted with an inert gas such as helium or argon.

In some cases, as mentioned above, a single carbonitride precursor that includes both carbon and nitrogen in the molecule can be used to form the amorphous carbonitride film 12. One example of such a single carbonitride precursor that can be employed is acetonitrile (CH₃CN). Other single carbonitride precursors beside acetonitrile can be used as long as the precursor includes carbon and nitrogen atoms therein. When a single carbonitride precursor is employed, an oxidant, as described above can also be used. The single carbonitride precursor can be used as is or diluted with an inert gas such as helium or argon. Other potential single carbonitride precursors include heterocyclic compounds such as pyrrole, imidazole, pyrazole, pyridine, pyrazine, pyrimidine, pyridazine, pyrazinyl, imidazolyl, pyrimidinyl, piperazine, triazine, amines such as methylamine, diamine ethane, diamine methane, aminoethane, aminopropane, azo, hydrzo, dimethylhydrazine, alkylazo compounds such as diethyldiazene, and amidines including acetamidine.

The gases may be introduced separately into a reactor chamber of a deposition tool, or some, or all of the gases may be admixed prior to being introduced into a reactor chamber of a deposition tool. Typically, the various gases are admixed in a mixing system prior to being introduced into the reactor chamber of a deposition tool. The reactor chamber of the deposition tool typically includes a substrate holder in which the substrate 10 is positioned within the reactor chamber. The distance of the substrate holder from the nozzle (or nozzles or showerhead) in which the reactant gas mixture (or gasses) is (are) introduced may vary within typical ranges well known to those skilled in the art. Typically, the substrate holder and hence substrate 10 is positioned a distance from 600 mils to 200 mils from the nozzle (or nozzles).

In addition, the gases may be introduced in a deposition tool in different stochiometries. In some cases, the carbon source may be introduced at a flow rate between 50 sccm and 2000 sccm, the nitrogen source may be introduced at a flow rate between 10 sccm and 50000 sccm, and the oxidant may be introduced at a flow rate between 10 sccm and 500 sccm. In other cases, the carbon source may be introduced at a flow rate between 50 sccm and 5000 sccm, the nitrogen source may be introduced at a flow rate between 10 sccm and 5000 sccm, and the oxidant may be introduced at a rate between 1 sccm and 1000 sccm. The inert gas may be introduced at a flow rate from 50 sccm to 50000 sccm.

In some further cases, the process pressure used in forming the amorphous carbonitride film 12 can be varied from 1 torr to 8 torr. In yet another embodiment of the invention, the substrate temperature during the deposition process can be fixed at 400° C. or 350° C. In an even further embodiment of the invention, the plasma can be generated using either a low frequency radio frequency (LFRF) plasma source at 100 MHz or a high frequency radio frequency HFRF plasma source at 13.56 GHz. The process pressure, substrate temperature and power used in generating the plasma are exemplary and other conditions are possible provided the selected conditions are capable of forming an amorphous carbonitride film having an extinction coefficient of greater than 0.15, an emissivity of greater than 0.8 and a minimum of hydrocarbon content.

In one embodiment of the invention, the amorphous carbonitride film 12 is formed by positioning substrate 10 within a parallel plate plasma enhanced chemical vapor deposition chamber. A reactant gas mixture, as defined above, is then introduced into the reactor chamber and thereafter an amorphous carbonitride film 12 having an extinction coefficient of greater than 0.15, an emissivity of greater than 0.8 and a minimum of hydrocarbon is formed.

Reference is now made to FIG. 31 which is a pictorial representation (through a cross sectional view) depicting a structure including a substrate 10 having an adhesion promoting layer 14, and an amorphous carbonitride film 12 formed thereon. It is observed that another adhesion promoting layer 14′ and another amorphous carbonitride film 12′ can be formed atop the amorphous carbonitride film 12 to form a layered structure as shown in FIG. 31. The structure in FIG. 31 may yet further include yet another adhesion promoter layer 14″ and yet another amorphous carbonitride film 12″ formed therein. The substrate 10 and amorphous carbonitride films 12, 12′ and 12″ are the same as those described above in FIG. 30. The adhesion promoting layers 14, 14′ and 14″ are thin layers typically from 1 nm to 20 nm in thickness. The presence of the adhesion promoting layer improves the adhesion of the amorphous carbonitride film to the substrate and to various layers within the structure. Such films including the combination of the amorphous carbonitride films and the adhesion promoting layers may be referred to as a gradient or layered amorphous carbonitride film. Typically, the adhesion promoting layers have a thickness that is less than the thickness of the amorphous carbonitride films.

The amorphous carbonitride films described hereinabove can be used for absorbing electromagnetic radiation having one or more wavelengths between 190 nm and 1000 nm. The amorphous carbonitride films described hereinabove can also be used in conjunction with conventional laser anneals to improve the heating uniformity across a plurality of surfaces.

The following examples are provided to illustrate the formation of amorphous carbonitride films having an extinction coefficient (k) of greater than 0.15, an emissivity of greater than 0.8 and a minimum of hydrocarbon. The following examples illustrate some advantages and/or improvements that can be obtained from such amorphous carbonitride films.

### Example 1

Amorphous carbonitride films were deposited onto an oxide coated silicon substrate using the following conditions: 400° C. deposition temperature, 500 watts LFRF, 220 mils, and 3 torr pressure. Propylene (C₃—H₆) was fixed at 1000 sccm, while the reactant gases (i.e. nitrogen and ammonia), and the oxidant (N₂O) were varied as detailed in Table 2. Refractive index (n) and extinction coefficient (k) were measured using an n&k tool.

TABLE 2
Amorphous carbonitride deposition conditions

| | Pressure | Temperature | C₃H₆ | N₂O | N₂ | NH₃ | He | |
|---|---|---|---|---|---|---|---|---|
| Sample | (torr) | (° C.) | (sccm) | (sccm) | (sccm) | (sccm) | (sccm) | k |
| 1 | 3 | 400 | 1000 | 80 | 0 | 0 | 0 | 0.15 |
| 2 | 3 | 400 | 1000 | 80 | 5000 | 70 | 0 | 0.19 |
| 3 | 3 | 400 | 1000 | 200 | 5000 | 70 | 0 | 0.30 |

As summarized in the Table 2, for Sample 1 deposited from propylene and N₂O only, the extinction coefficient was 0.15. However, by formation of the carbonitride in Sample 2 of this example with the addition of nitrogen, and ammonia the extinction coefficient, k was increased to 0.19. In Sample 3 of this example an additional increase in N₂O increased k to 0.3. The oxidant, N₂O in this particular case was essential in increasing k.

### Example 2

Amorphous carbonitride films were deposited onto an oxide coated silicon substrate with deposition conditions as summarized in Table 3 at 400° C. Propylene (C₃H₆) was fixed at 500 sccm, oxygen was fixed at 50 sccm, mil spacing was fixed at 220 mils and pressure was fixed at 4 torr. Refractive index (n) and extinction coefficient (k) were measured using an n&k tool. Oxygen was used as the oxidant as shown in Table 3.

TABLE 3
Deposition Conditions

| | | | | | | | | | CH Peak |
|---|---|---|---|---|---|---|---|---|---|
| Temp. | HFRF | LFRF | Press. | C₃H₆ | O₂ | N₂ | NH₃ | | area/thick |
| (° C.) | (watts) | (watts) | (torr) | (sccm) | (sccm) | (sccm) | (sccm) | k | (μm) |
| 400 | 1000 | 0 | 4 | 500 | 50 | 5000 | 70 | 0.25 | 1.3 |
| 400 | 0 | 500 | 4 | 500 | 50 | 5000 | 70 | 0.25 | 1.7 |
| 400 | 0 | 500 | 4 | 500 | 50 | 10000 | 70 | 0.29 | 0.6 |

Switching from HFRF to LFRF plasma power resulted in a halving of the normalized hydrocarbon content as observed by FTIR. The normalized hydrocarbon content is defined by integrating under the C—H stretching peak in the FTIR spectra from 3170-2750 cm⁻¹ and dividing the integrated peak area by the film thickness in microns.

### Example 3

Thin layers of amorphous carbonitride (ACN) films were deposited on top of each other with varying plasma frequencies to achieve thicker films. Such a structure is shown, for example, in FIG. 31. These layers were addressed as adhesion promoting layers in this aspect. This was done to avoid the delamination of a thick film due to inherent intrinsic compressive stress. Five ACN films were deposited at 400° C. and 220 mils. The propylene and oxygen were fixed at 500 sccm and 10 sccm respectively. A thin adhesion promoting layer (ACN1 time: 10 sec deposition time) at 1000 W HFRF (13.56 MHz) was deposited initially and in between thicker ACN layers (ACN2 time: 60 sec deposition time) in order to achieve a thicker film with a higher k and emissivity. The substrates were then annealed using a laser at 1350° C. The emissivity of the substrates were measured and listed in the Table 4, with other details.

TABLE 4
Deposition Conditions

| | | ACN1 | ACN1 | ACN1 | ACN2 | ACN2 | | | | |
|---|---|---|---|---|---|---|---|---|---|---|
| | Pressure | N₂ | NH₃ | HFRF | N₂ | NH₃ | ACN2 | | 3 cycle | 3 cycle |
| Sample | (torr) | (sccm) | (sccm) | (watts) | (sccm) | (sccm) | LFRF | cycles | emissivity | k |
| 1 | 4 | 2500 | 100 | 1000 | 1000 | 300 | 600 | 3 | 0.904 | 0.294 |
| 2 | 4 | 2500 | 300 | 1000 | 2500 | 100 | 600 | 3 | 0.826 | 0.261 |
| 3 | 4 | 2500 | 10 | 1000 | 5000 | 10 | 600 | 3 | 0.887 | 0.356 |
| 4 | 6 | 5000 | 10 | 1000 | 5000 | 70 | 600 | 3 | 0.861 | 0.253 |
| 5 | 6 | 5000 | 70 | 1000 | 5000 | 100 | 600 | 3 | 0.904 | 0.327 |

Surface resistance measurements were taken with the last four conditions. As shown in FIG. 32, the surface resistance of the ACN results was better than or comparable to 550° C. ACL films. ACN films can be removed using a down stream oxygen plasma ash technique followed by sulfuric nitric acid dip. The Rₛ measurements performed on 400° C. ACN films are plotted together with the existing 550° C. ACL film in FIG. 32.

### Example 4

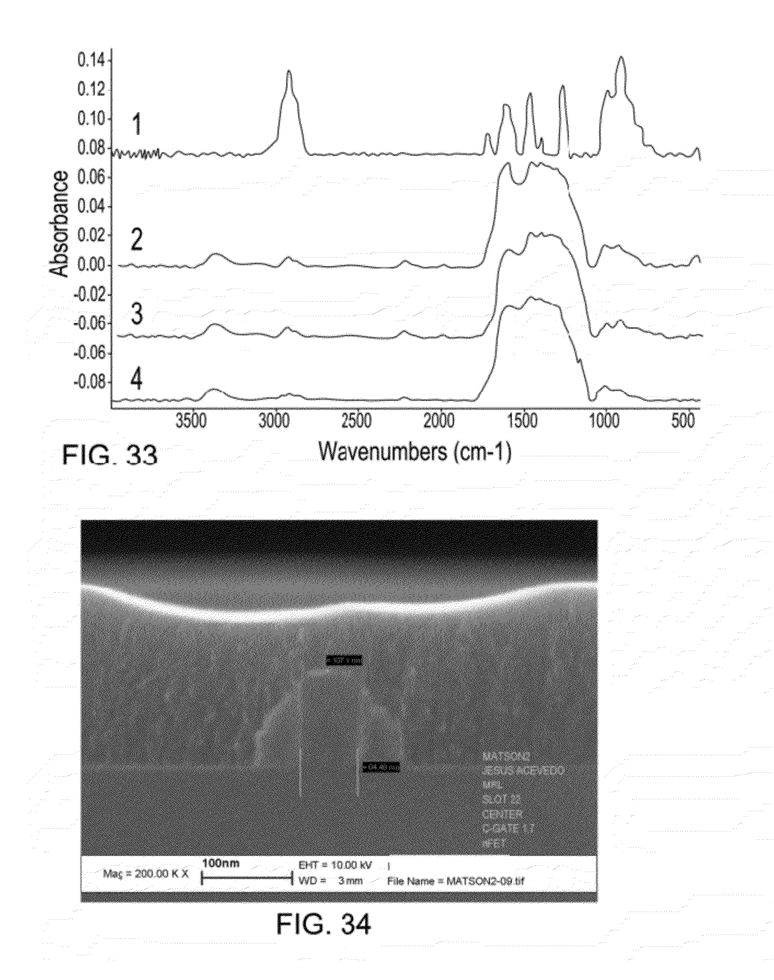

As shown in FIG. 33, in some cases, addition of nitrogen is critical in forming the amorphous carbonitride film. The FTIR spectra of Sample 1 of this example deposited at 350° C. without nitrogen or ammonia is consistent with formation of an amorphous carbon film. Sample 1 of this example differs from the films depicted in FIG. 29. The addition of oxygen during deposition resulted in the formation of C═O species in the film as evidenced by the FTIR absorption at 1700 cm⁻¹. Film properties are summarized in Table 5. Without N₂ or ammonia in the recipe the resultant film Sample 1 of this example had an extinction coefficient of 0.13 and a normalized hydrocarbon content of 3. Formation of the carbonitride by addition of ammonia and/or ammonia during deposition resulted in increased k>0.2 and reduction of the normalized hydrocarbon content to 1.

TABLE 5
Deposition Conditions

| | | | | | | | | | | CH peak |
|---|---|---|---|---|---|---|---|---|---|---|
| | Temperature | Pressure | LFRF | C₃H₆ | O₂ | N₂ | NH₃ | He | | area/thick- |
| Sample | (° C.) | (torr) | (watts) | (sccm) | (sccm) | (sccm) | (sccm) | (sccm) | k | ness μm |
| 1 | 350 | 8 | 500 | 350 | 100 | 0 | 0 | 5000 | 0.13 | 3 |
| 2 | 350 | 8 | 500 | 350 | 100 | 0 | 300 | 5000 | 0.21 | 1 |
| 3 | 350 | 8 | 500 | 350 | 100 | 2500 | 0 | 5000 | 0.27 | 1 |
| 4 | 350 | 8 | 500 | 350 | 100 | 2500 | 300 | 5000 | 0.32 | 1 |

### Example 5

The effect of He dilution on k was also observed, and it was determined that by increasing the He dilution resulted in an ACN film having a larger k. In this example, the deposition temperature was 350° C., 220 mil, the pressure was 4 torr. Table 6 includes the other conditions used in this example. As shown in the table by increasing He flow k can be increased.

TABLE 6
Deposition Conditions

| | | | | | | | | | | CH peak |
|---|---|---|---|---|---|---|---|---|---|---|
| | Temperature | Pressure | LFRF | C₃H₆ | O₂ | N₂ | NH₃ | He | | area/thick- |
| Sample | (° C.) | (torr) | (watts) | (sccm) | (sccm) | (sccm) | (sccm) | (sccm) | k | ness μm |
| 1 | 350 | 4 | 500 | 500 | 10 | 2500 | 300 | 1000 | 0.15 | 1.5 |
| 2 | 350 | 4 | 500 | 500 | 10 | 2500 | 300 | 3000 | 0.24 | 1.4 |
| 3 | 350 | 4 | 500 | 500 | 10 | 2500 | 300 | 5000 | 0.26 | 0.9 |

### Example 6

Amorphous carbonitride films were deposited at 350° C. with varying amounts of oxygen and other conditions as mentioned in this example. The carbon precursor. i.e., C₃H₆, was flowed at 350 sccm, 1\17 at 2500 sccm. NH₃ at 300 sccm, He at 5000 sccm and a LFRF power of 500 watts (approximately 100 MHz) and a pressure of 4 torr were employed. The optical properties measured on the films indicated that extinction coefficient of such films were very high. See Table 7.

TABLE 7
Deposition Conditions

| | Temperature | Pressure | LFRF | C₃H₆ | O₂ | N₂ | NH₃ | He | |
|---|---|---|---|---|---|---|---|---|---|
| Sample | (° C.) | (torr) | (watts | (sccm) | (sccm) | (sccm) | (sccm) | (sccm) | k |
| 1 | 350 | 4 | 500 | 350 | 10 | 2500 | 300 | 5000 | 0.36 |
| 2 | 350 | 4 | 500 | 350 | 50 | 2500 | 300 | 5000 | 0.39 |
| 3 | 350 | 4 | 500 | 350 | 100 | 2500 | 300 | 5000 | 0.32 |

These films were then subjected to flash lamp annealing and SEM micrographs were obtained on ACN films after flash anneal applications. It was evident from the SEM micrographs that ACN films deposited at 350° C. survived the flash lamp annealing and also they are very conformal with intact microstructure after annealing. One such SEM micrograph is shown, for example, in FIG. 34. After flash anneal, thickness, n and k are relatively unchanged after anneal indicative that the films are very stable and less prone to outgassing at higher temperatures.

### Example 7

As shown in FIG. 35, for semiconductor-on-insulator (SOI) technology, the SOI substrate without an absorber layer was highly reflective to light (wavelength between 300 nm to 400 nm) generated by an arc-lamp from a high temperature millisecond flash anneal tool. As shown in FIG. 35, after coating an SOI substrate with an amorphous carbon layer from the prior art (Sample 1, Table 1) and an amorphous carbonitride absorber layer discussed herein (Sample 2. Table 7) reflectivity from the SOI substrate was substantially reduced from 40% for uncoated SOI substrate to 10%. The carbonitride absorber layer deposited at 350° C. (Sample 2. Table 7) was as effective as the amorphous carbon layer deposited at 550° C. in reducing reflectivity of the SOI substrate.

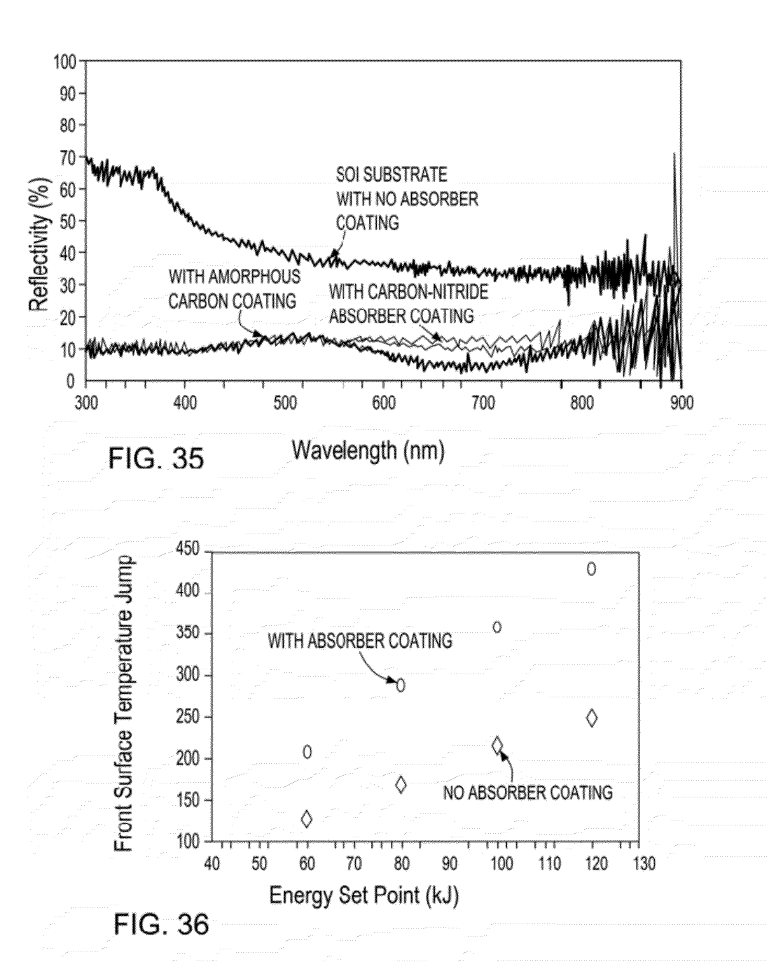

Reduction in reflectivity enables higher front surface temperatures during flash anneal which, in turn, enables lower backside substrate temperatures to minimize dopant movement, source/drain junction profile broadening and increased junction depth. Shown in FIG. 36, for each energy set point of the flash anneal lamps a substrate coated with an absorber layer had a 100-200° C. increased front surface temperature than an uncoated substrate. Thus, for a given maximum available power from the arc-lamp of the flash anneal tool, the high reflectance from SOI substrate severely limits the temperature-jump for the SOI device substrate during a high temperature mill-second flash anneal.

Flash anneal and laser spike anneals have been introduced to activate dopants in milliseconds. Boron dopant deactivation is proposed to be due to the formation of inactive boron-interstitial clusters (BICs) as a result of the release of silicon interstitials from the end-of-range (EOR) defects upon annealing. Carbon atoms are reported to be an effective sink for silicon interstitials and that extended defect levels are reduced or eliminated with increasing carbon dose. See, Chyiu Hyia Poon, JOURNAL OF APPLIED PHYSICS 103, 084906 2008. In this example, the carbonitride absorber layer deposited at 350° C. (Sample 2. Table 7) was employed as an efficient absorber coating for a flash anneal so that the arc-lamp light from the flash anneal is efficiently absorbed and subsequently increased the temperature jump for the SOI device substrate to achieve improved C substitution in SiC source/drain and to maximize junction activation for 22 nm CMOS technology devices and beyond.

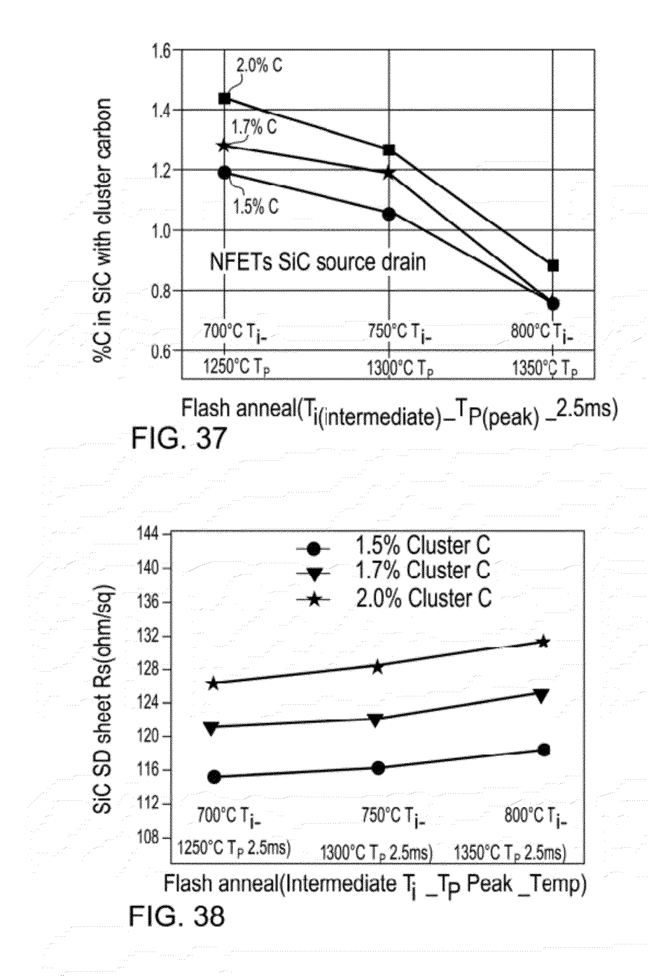

Shown in FIG. 37, is the dependence of improved C substitution in SiC source/drain regions on peak and intermediate temperature during a flash activation anneal. The substrate was heated to an intermediate temperature of 700° C. and the lamps were flashed to spike the peak temperature to at least 1250° C. A % C content of 1.2-1.5% was achieved in the SiC dependant on the starting implanted carbon concentration. At a higher intermediate temperature of 800° C., the % C content was reduced to 0.7-0.9%. The measured sheet resistance of the source/drain contact shown in FIG. 38 with intermediate temperature of 700° C. and peak temperature of 1250° C. was 114-126 ohm/square with resistance increasing slightly from 114 to 16 ohm/square with increasing carbon concentration.

What is claimed is:

1. A method comprising:
providing a semiconductor structure; and
subjecting at least a portion of said structure to a long flash anneal process.

2. The method of claim 1, wherein said long flash anneal process comprises a peak temperature of about 1300 degrees centigrade maintained for about 2.5 milliseconds.

3. The method of claim 1, wherein said structure provided in said providing step has a gate pitch of no more than about 80 nanometers.

4. The method of claim 1, further comprising maintaining said semiconductor structure at an intermediate temperature of about 300 to about 900 degrees centigrade prior to said long flash anneal process.

5. The method of claim 4, wherein said intermediate temperature comprises about 400 to about 900 degrees centigrade.

6. The method of claim 4, wherein said intermediate temperature comprises about 300 to about 400 degrees centigrade and said semiconductor structure comprises a silicide.

7. The method of claim 6, wherein said long flash anneal process comprises a peak temperature of about 900 to about 950 degrees centigrade maintained for about 1 to about 5 milliseconds.

8. The method of claim 1, wherein said long flash anneal process comprises a peak temperature of about 1200 to about 1300 degrees centigrade maintained for about 1 to about 2.5 milliseconds.

9. The method of claim 1, wherein said long flash anneal process comprises a peak temperature of about 1200 to about 1350 degrees centigrade maintained for about 1 to about 5 milliseconds.

10. The method of claim 1, wherein said long flash anneal process comprises a peak temperature of about 950 to about 1300 degrees centigrade maintained for about 1 to about 2.5 milliseconds.

11. The method of claim 1, wherein said long flash anneal process comprises a peak temperature of about 950 to about 1250 degrees centigrade maintained for about 1 to about 2.5 milliseconds.

12. The method of claim 1, wherein said long flash anneal process comprises a peak temperature of about 1150 to about 1300 degrees centigrade maintained for about 1 to about 5 milliseconds.

13. The method of claim 1, wherein said structure provided in said providing step comprises a silicon body having a thickness of no more than about 10 nanometers.

14. The method of claim 1, further comprising applying an absorber to at least a portion of said semiconductor structure prior to said long flash anneal process, said absorber having a low deposition temperature.

15. The method of claim 14, wherein said low deposition temperature is no greater than about 400 degrees centigrade.

16. The method of claim 14, wherein said low deposition temperature is no greater than about 450 degrees centigrade.

17. The method of claim 14, wherein said low deposition temperature ranges from about 250 degrees centigrade to about 450 degrees centigrade.

18. The method of claim 14, wherein said low deposition temperature ranges from about 350 degrees centigrade to about 400 degrees centigrade.

19. The method of claim 14, wherein said long flash anneal process comprises a peak temperature of about 1300 degrees centigrade maintained for about 2.5 milliseconds, and wherein said low deposition temperature is no greater than about 400 degrees centigrade.

20. The method of claim 14, wherein said long flash anneal process comprises a peak temperature of about 1100 to about 1350 degrees centigrade maintained for about 1 to about 5 milliseconds, and wherein said low deposition temperature ranges from about 250 degrees centigrade to about 450 degrees centigrade.

21. The method of claim 14, wherein, in said applying step, said absorber comprises an amorphous carbonitride film.

22. The method of claim 21, wherein, in said applying step, said amorphous carbonitride film has an extinction coefficient of greater than 0.2 and an emissivity of greater than 0.8.

23. The method of claim 22, wherein said subjecting step comprises causing electromagnetic radiation having at least one wavelength between 190 nm and 1000 nm to be absorbed by said absorber.

24. The method of claim 14, wherein:
said long flash anneal process comprises a peak temperature of about 1100 to about 1350 degrees centigrade maintained for about 1 to about 5 milliseconds;
said low deposition temperature ranges from about 250 degrees centigrade to about 450 degrees centigrade; and
in said applying step, said absorber comprises an amorphous carbonitride film.

25. The method of claim 24, wherein, in said applying step, said amorphous carbonitride film has an extinction coefficient of greater than 0.2 and an emissivity of greater than 0.8.

26. The method of claim 25, wherein said subjecting step comprises causing electromagnetic radiation having at least one wavelength between 190 nm and 1000 nm to be absorbed by said absorber.

27. The method of claim 14, further comprising maintaining said semiconductor structure at an intermediate temperature of about 300 to about 900 degrees centigrade prior to said long flash anneal process, for about zero to about 5 seconds.

28. The method of claim 1, wherein said semiconductor structure provided in said providing step comprises:
a plurality of NFET portions;
a plurality of PFET portions;
a plurality of shallow trench isolation regions separating said NFET portions and said PFET portions;
a plurality of NFET source-drain regions associated with said NFET portions and having been subjected to e-SiC chemical vapor deposition;
a plurality of PFET source-drain regions associated with said PFET portions and having been subjected to e-SiGe chemical vapor deposition;
a plurality of NFET gates intermediate given ones of said source-drain regions associated with said NFET portions;
a plurality of PFET gates intermediate given ones of said source-drain regions associated with said PFET portions;
a plurality of NFET halo regions intermediate said given ones of said source-drain regions associated with said NFET portions and said NFET gates; and
a plurality of PFET halo regions intermediate said given ones of said source-drain regions associated with said PFET portions and said PFET gates.

29. The method of claim 1, wherein said structure provided in said providing step comprises a metal high-k gate stack.
